(19) United States
(12) Patent Application Publication
(10) Pub. No.: US 2025/0326316 A1
(43) Pub. Date: Oct. 23, 2025

(54) MEASURING BATTERY CAPACITY OF A BATTERY INSTALLED ON A VEHICLE THROUGH VEHICLE-TO-GRID (V2G) DISCHARGE AND CHARGE CYCLING OPERATION

(71) Applicant: Volvo Truck Corporation, Göteborg (SE)

(72) Inventors: Simon Brunet, Landvetter (SE); Tommy Hjelle, Torslanda (SE)

(21) Appl. No.: 19/085,034

(22) Filed: Mar. 20, 2025

(30) Foreign Application Priority Data
Apr. 17, 2024 (EP) 24170768.6

(51) Int. Cl. B60L 53/62; B60L 53/16; B60L 53/66; B60L 55/00; B60L 58/12; G01R 31/388; H02J 7/00

(52) U.S. Cl. CPC B60L 53/62; B60L 53/66; B60L 55/00; G01R 31/388; H02J 7/0068; H02J 7/007182; B60L 53/16; B60L 58/12

(57) ABSTRACT

Aspects disclosed herein involve measuring battery capacity of a battery installed on a vehicle through a vehicle-to-grid (V2G) discharge and charge cycling operation. The EV is configured to perform the discharge/charge cycle in the discharge/charge operational mode cooperatively through a power connection to a charging station configured to operate in a V2G mode to determine battery capacity. The charging station is not only controllable by the EV to charge its battery from grid power, but the charging station is also controllable by the EV to discharge energy from its battery back to the grid in a V2G operation. The EV can disable on-board, non-essential power consuming devices before starting the discharge cycle so that measured discharge energy can be controlled to be as steady state as possible to allow a more accurate measurement of the discharge energy from the battery.

### PRIORITY APPLICATIONS

The present application claims priority to European Patent Application No. 24170768.6, filed on Apr. 17, 2024, and entitled “MEASURING BATTERY CAPACITY OF A BATTERY INSTALLED ON A VEHICLE THROUGH VEHICLE-TO-GRID (V2G) DISCHARGE AND CHARGE CYCLING OPERATION,” which is incorporated herein by reference in its entirety.

### TECHNICAL FIELD

The disclosure relates generally to charging and discharging of a battery used to power an electric vehicle (EV), including battery electric vehicles (BEVs), plug-in hybrid electric vehicles (PHEVs), and hybrid electric vehicles (HEVs). In particular aspects, the disclosure relates to measuring battery capacity of a battery installed on a vehicle through a vehicle-to-grid (V2G) discharge and charge cycling operation.

The disclosure can be applied to electric heavy-duty vehicles, such as electric trucks, electric buses, and electric construction equipment, among other vehicle types. Although the disclosure may be described with respect to a particular vehicle, the disclosure is not restricted to any particular vehicle.

### BACKGROUND

Electric vehicles (EVs) have an on-board battery (ies) to provide power for vehicle operation. Battery electric vehicles (BEVs) include a battery as their sole source of power. Thus, BEVs are configured to operate exclusively on battery power at all times during their operation. On the other hand, plug-in hybrid electric vehicles (PHEVs) are only configured to operate exclusively on battery power for limited periods of time depending on battery capacity and/or or operational algorithm settings, and then operate on combustion engine power at other times. In the case of BEVs, the vehicle will no longer be able to continue operation when the battery power source no longer has a sufficient state of charge (SOC) (i.e., energy) to operate the vehicle. In both BEVs and PHEVs, a battery SOC (i.e., remaining energy capacity of the battery) can be estimated by an advanced battery SOC estimation algorithm performed by an on-board computer in the vehicle. The battery SOC can be used by the on-board computer to make decisions or suggestions on when and/or where the user should perform battery charging to re-charge the battery. The battery SOC can also be displayed to a user as a remaining drive mileage or percentage of remaining capacity, for example, so that the user can use this information to determine when battery charging may be appropriate or desired. However, older legacy electric vehicles may not be equipped with a system that estimates battery SOC. Even if an EV is equipped with a system that estimates the battery SOC, the system may be based on an older, less accurate battery SOC estimation algorithm. Also, a battery SOC estimate algorithm may become less accurate over time after a large number of charges and discharges due to the aging of the battery, known as “capacity fade.” Battery aging can cause a gradual decrease in the battery's ability to store and deliver charge over time, thus causing assumptions about how charging will affect the battery SOC to be less accurate.

If an EV is not equipped with an on-board battery SOC estimation system, it may be necessary to periodically determine the exact capacity of the battery to determine if battery capacity remains sufficient for the needs or desires of the vehicle operator. Even if an EV includes an on-board battery SOC estimation system, the estimated battery SOC provided by such system may become less accurate over time due to battery aging and/or incomplete discharge/charge cycles. A full discharge/charge cycle provides more data points for accurate calibration and adjustment of the battery SOC estimation algorithm. Thus, it may still be necessary to periodically determine the exact capacity of a vehicle battery even with an on-board battery SOC estimation system. For example, a technician can be called out to the location of the vehicle to perform the full discharge and charge cycle on site at a vehicle to determine the true battery capacity of the vehicle battery. In this manner, if the true battery capacity of the vehicle battery has degraded below a desired or necessary capacity, the battery can be repaired (by replacing bad cells) or replaced. The way to truly measure the battery capacity of the vehicle battery is to fully discharge the battery followed by a full charging of the battery back to a full charge. During the charging time, the energy transferred to the battery can be measured (e.g., by integrating power transfer) to provide an accurate, current battery capacity of the battery available for energy storage and discharge. The actual battery capacity can then be reported for decisions about battery repair and/or replacement, if needed. The measured transfer energy can also be used to recalibrate settings for a battery SOC estimation algorithm for correlating charging to battery SOC.

### SUMMARY

Aspects disclosed herein involve measuring battery capacity of a battery installed on a vehicle through a vehicle-to-grid (V2G) discharge and charge cycling operation. The vehicle is an electric vehicle (EV) in that it includes an installed battery (ies) to provide a power source for operation. For example, the EV could be a battery EV (BEV) or plug-in hybrid EV (PHEV) that has the capability of recharging its battery (ies) from an external charging source (e.g., a charging station). To determine the actual battery capacity of the battery (ies), the EV can be configured to be put into a discharge/charge operational mode to perform a discharge/charge cycle to fully charge and discharge the battery. During the charging time, the energy transferred to the battery is measured (e.g., by integrating power transfer) to provide an accurate battery capacity of the battery available for energy storage and discharge. In exemplary aspects, the EV is configured to perform the discharge/charge cycle in the discharge/charge operational mode cooperatively through a power connection to a battery charging station (referred to as “charging station”) that is configured to operate in a V2G mode. In this regard, the charging station is not only controllable by the EV to charge its battery from grid power, but the charging station is also controllable by the EV to discharge energy from its battery back to the grid in a V2G operation. For example, the charging station may be compatible with a V2G operational standard or specification that allows for EV batteries to be charged to store excess energy from the power grid and then be discharged back to the power grid at higher energy demand to ease pressure on the power grid infrastructure. By the EV being able to electronically request performance of the discharge/charge cycle through a connected charging station capable of charging and discharging its battery, discharging times may also be faster than can be performed by activation of on-board power-consuming devices in the EV. Also, by the EV being able to request performance of the discharge/charge cycle through a connected charging station, energy that is discharged from the EV battery can be conserved by being transferred back to the power grid.

Also, by the EV being able to electronically request performance of the discharge/charge cycle through a connected charging station capable of charging and discharging its battery, the EV can be scheduled and/or controlled, including remotely controlled, to perform the discharge/charge cycle at any time when connected to the charging station without the need for human action or intervention.

In an exemplary aspect, to perform the discharge/charge cycle for the EV battery, the EV is placed into a discharge/charge operational mode. In the discharge/charge operational mode, the EV is configured to communicate a discharge request to the charging station (e.g., over a vehicle charging port connected to the charging station) to switch the charging station to a V2G mode to fully discharge the battery to the power grid connected to the charging station in a discharge mode. The EV measures the discharge energy from the battery during discharge (e.g., by integrating power transfer to the charging station over discharging time). The measured discharge energy can be communicated and/or stored by an on-board computer (e.g., a vehicle electronic control unit (ECU)) in the EV. In one aspect, the EV disables on-board, non-essential power-consuming devices before starting the discharge cycle so that the measured discharge energy can be controlled to be as steady state (e.g., constant) as possible to allow a more accurate measurement of the discharge energy from the battery. Also, as an example, the EV may request that the charging station discharge its battery with a first higher steady state current for initial faster discharging until its battery reaches a first predetermined lower overall voltage. The first higher steady state current can achieve a balance between a faster discharge time, while at the same time not discharging energy so fast that excess energy losses are generated by the battery from discharging that can increase battery aging and degrade battery capacity. After the battery reaches the first predetermined lower overall voltage, the EV may request that the charging station continue discharging its battery with a first lower steady state current until all the battery cells of the battery are within the first predetermined lower voltage (i.e., achieve voltage equalization for a full discharge).

Then, still in the discharge/charge operational mode, the EV can communicate a charging request to the charging station (e.g., over the vehicle charging port connected to the charging station) to fully charge the battery from the power grid connected to the charging station in a charge mode. The EV may optionally wait a period of time after the discharge cycle and before communicating the charging request to the charging station to allow the energy stored in battery cells of the battery (ies) to balance. The EV requests that the connected charging station fully charge the battery from power from the power grid delivered through the charging station. The EV measures the charge energy delivered to the battery during charging (e.g., by integrating power transfer to the battery over the charging time). As an example, the EV may request that the charging station charge its battery with a second higher steady state current until its battery reaches a second predetermined higher overall voltage, and then request that the charging station charge its battery with a second lower steady state current until the battery cells reach the second predetermined higher voltage (i.e., achieve voltage equalization for a full charge). This has the advantage of providing an initial fast charging time, but as the battery SOC approaches its maximum SOC, the second lower steady state current is used to avoid excess energy resulting in heat generation through losses which can increase battery aging and degrade battery capacity.

The EV can use the measured energy transferred during the discharge and charge cycles to determine the battery capacity of its battery (ies). The measured discharge and charge energy can be stored and/or displayed to a technician or an operator of the EV. The technician or operator of the EV can use the determined battery capacity of the battery (ies) of the EV to determine if the battery (ies) should be repaired or replaced. Also, the determined battery capacity of the battery (ies) can be used by the EV to update its battery SOC estimation system and algorithm so that a more accurate SOC can be determined and/or displayed to the operator of the vehicle.

Note that the EV can also be configured in the discharge/charge operational mode to first optionally request that the connected charging station fully charge the battery from power from the power grid delivered through the charging station in an initial charge mode before the discharge mode is performed. In the initial charge mode, the EV is configured to communicate an initial charging request to the charging station (e.g., over the vehicle charging port connected to the charging station) to fully charge the battery from the power grid connected to the charging station. As an example, the EV may request that the charging station charge its battery with an initial third higher current for initial faster charging until its battery reaches a third predetermined higher overall voltage, and then request that the charging station charge its battery with a third lower current until the battery cells reach the third predetermined higher voltage (i.e., achieve voltage equalization for a full charge). This has the advantage of providing an initial faster charging time, but as the battery SOC approaches its maximum SOC, the third lower current is used to avoid excess energy resulting in heat generation through losses which can increase battery aging and degrade battery capacity.

In another exemplary aspect, the EV can be configured to initiate the discharge/charge operational mode with a connected charging station to determine the actual battery capacity of its battery (ies) based on a time-of-day (TOD) schedule, such as in the event power charges are based on TOD rates. In this manner, the EV can be configured to request performing the charging cycle(s) at times when power is less expensive and/or in lower demand, and perform the discharging cycle(s) at times when power is more expensive and/or in higher demand.

According to a first aspect of the disclosure, a computer system including processing circuitry configured to receive a request for a vehicle to enter a discharge/charge operational mode while a vehicle charging port of the vehicle is coupled to an external charging station configured to operate in a vehicle-to-grid (V2G) mode is disclosed. In response to the request for the vehicle to enter the discharge/charge operational mode, the processing circuitry is configured to deactivate power consuming devices in the vehicle not essential to the vehicle operating in the discharge/charge operational mode, communicate a discharge request to the external charging station to discharge energy from a battery in the vehicle to a power grid coupled to the external charging station at a first steady state current in a discharge mode, measure the discharged energy from the battery in the discharge mode, and detect the battery at a first predetermined lower voltage in the discharge mode. In response to detecting the battery at the first predetermined lower voltage in the discharge mode, the processing circuitry is configured to communicate a charge request to the external charging station to deliver charge energy to the battery from the power grid at a second steady state current in a charge mode, and measure the charge energy delivered to the battery in the charge mode. A technical benefit may include an EV that includes the computer system being able to electronically request performance of the discharge/charge cycle through a connected charging station capable of charging and discharging its battery, as discharging times may also be faster than can be performed by activation of on-board power-consuming devices in the EV. Also, by the EV being able to request performance of the discharge/charge cycle through a connected charging station, energy that is discharged from the EV battery can be conserved by being transferred back to the power grid.

Optionally in some examples, including in at least one preferred example, the processing circuitry is configured to communicate the discharge request by being configured to communicate a first discharge request to the external charging station to discharge energy from the battery in the vehicle to the power grid coupled to the external charging station at a first higher steady state current in the discharge mode, and detect an overall voltage of the battery at the first predetermined lower voltage in the discharge mode. In response to detecting the overall voltage of the battery at the first predetermined lower voltage in the discharge mode, the processing circuitry is further configured to communicate a second discharge request to the external charging station to discharge energy from the battery in the vehicle to the power grid at a first lower steady state current lower than the first higher steady state current in the discharge mode, and detect a voltage of cells of the battery at the first predetermined lower voltage in the discharge mode. In response to detecting the voltage of the cells of the battery at the first predetermined lower voltage in the discharge mode, the processing circuitry is further configured to communicate the charge request to the external charging station to deliver the charge energy to the battery from the power grid at the second steady state current in the charge mode, and measure the charge energy delivered to the battery in the charge mode. A technical benefit may include that using the first higher steady state current can achieve a balance between a faster discharge time, while at the same time not discharging energy so fast that excess energy losses generated by the battery from discharging can increase battery aging and degrade battery capacity. After the battery reaches the first predetermined lower overall voltage, the EV may request that the charging station continue discharging its battery with a first lower steady state current until all the battery cells of the battery are within the first predetermined lower voltage (i.e., achieve voltage equalization for a full discharge).

Optionally in some examples, including in at least one preferred example, the first predetermined lower voltage is approximately 610-620 Volts (V), the first lower steady state current is less than 5 Amps (A), and the first higher steady state current is between 5 A and 50 A. A technical benefit may include that using the first higher steady state current can achieve a balance between a faster discharge time, while at the same time not discharging energy so fast that excess energy losses generated by the battery from discharging can increase battery aging and degrade battery capacity. After the battery reaches the first predetermined lower overall voltage, the EV may request that the charging station continue discharging its battery with a first lower steady state current until all the battery cells of the battery are within the first predetermined lower voltage (i.e., achieve voltage equalization for a full discharge).

Optionally in some examples, including in at least one preferred example, the processing circuitry is further configured to, in response to detecting the battery at the first predetermined lower voltage in the discharge mode, wait for a predetermined amount of time before communicating the charge request to the external charging station. A technical benefit may include allowing the energy stored in the cells of the battery to balance when discharged.

Optionally in some examples, including in at least one preferred example, the processing circuitry is further configured to detect when the battery is at a second predetermined higher voltage in the charge mode. In response to detecting the battery is at the second predetermined higher voltage in the charge mode, the processing circuitry is further configured to disable the discharge/charge operational mode. A technical benefit may include the advantage of determining when the battery has been sufficient charged.

Optionally in some examples, including in at least one preferred example, the processing circuitry is further configured to communicate the charge request by being configured to communicate a first charge request to the external charging station to deliver the charge energy to the battery from the power grid at a second higher steady state current in the charge mode, and detect an overall voltage of the battery at the second predetermined higher voltage in the charge mode. In response to detecting the overall voltage of the battery at the second predetermined higher voltage in the charge mode, the processing circuitry is further configured to communicate a second charge request to the external charging station to deliver the charge energy to the battery from the power grid at a second lower steady state current lower than the second higher steady state current in the charge mode, and detect a voltage of cells of the battery at the second predetermined higher voltage in the charge mode. In response to detecting the voltage of the cells of the battery at the second predetermined higher voltage in the charge mode, the processing circuitry is further configured to disable the discharge/charge operational mode. A technical benefit may include the advantage of providing an initial faster charging time, but as the battery SOC approaches its maximum SOC, a lower current is used to avoid excess energy through losses resulting in heat generation, which can increase battery aging and degrade battery capacity.

Optionally in some examples, including in at least one preferred example, the second predetermined higher voltage is approximately 710-720 Volts (V), the second lower steady state current lower is less than 5 Amps (A), and the second higher steady state current lower is greater than 5 A. A technical benefit may include the advantage of providing an initial faster charging time, but as the battery SOC approaches its maximum SOC, a lower current is used to avoid excess energy through losses resulting in heat generation, which can increase battery aging and degrade battery capacity.

Optionally in some examples, including in at least one preferred example, the processing circuitry is further configured to communicate the charge request by being configured to communicate a first charge request to the external charging station to deliver the charge energy to the battery from the power grid at a second higher steady state current in the discharge mode, and detect an overall voltage of the battery at a second predetermined higher voltage in the charge mode. In response to detecting the overall voltage of the battery at the second predetermined higher voltage in the charge mode, the processing circuitry is further configured to communicate a second charge request to the external charging station to deliver the charge energy to the battery from the power grid at a second lower steady state current lower than the second higher steady state current in the charge mode, and detect a voltage of the cells of the battery at the second predetermined higher voltage in the charge mode. In response to detecting the voltage of the cells of the battery at the second predetermined higher voltage in the charge mode, the processing circuitry is further configured to disable the discharge/charge operational mode. A technical benefit may include the advantage of providing an initial faster charging time, but as the battery SOC approaches its maximum SOC, a lower current is used to avoid excess energy through losses resulting in heat generation, which can increase battery aging and degrade battery capacity.

Optionally in some examples, including in at least one preferred example, the processing circuitry is further configured to, in response to the request for the vehicle to enter the discharge/charge operational mode, prior to communicating the discharge request, communicate an initial charge request to the external charging station to deliver initial charge energy to the battery from the power grid at a third current in an initial charge mode, and detect when the battery is at a third predetermined higher voltage in the initial charge mode. In response to detecting the battery is at the third predetermined higher voltage in the initial charge mode, the processing circuitry is further configured to communicate the discharge request to the external charging station. A technical benefit may include charging the battery at a higher current to more quickly charge the battery and therefore, to more quickly perform the discharge/charge process.

Optionally in some examples, including in at least one preferred example, the processing circuitry is further configured to communicate the initial charge request by being configured to communicate a first initial charge request to the external charging station to deliver the charge energy to the battery from the power grid at a third higher current in the initial charge mode, and detect an overall voltage of the battery at the third predetermined higher voltage in the initial charge mode. In response to detecting the overall voltage of the battery at the third predetermined higher voltage in the initial charge mode, the processing circuitry is further configured to communicate a second initial charge request to the external charging station to deliver the charge energy to the battery from the power grid at a third lower current lower than the third higher current in the initial charge mode, and detect a voltage of cells of the battery at the third predetermined higher voltage in the initial charge mode. In response to detecting the voltage of the cells of the battery at the third predetermined higher voltage in the initial charge mode, the processing circuitry is further configured to communicate the discharge request to the external charging station. A technical benefit may be the advantage of providing an initial fast charging time, but as the battery SOC approaches its maximum SOC, the second lower steady state current is used to avoid excess energy through losses resulting in heat generation, which can increase battery aging and degrade battery capacity.

Optionally in some examples, including in at least one preferred example, the third predetermined higher voltage is approximately 710-720 Volts (V), the third lower current is less than 5 Amps (A), and the third higher current is between 5 A and 50A. A technical benefit may be the advantage of providing an initial fast charging time, but as the battery SOC approaches its maximum SOC, the second lower steady state current is used to avoid excess energy through losses resulting in heat generation, which can increase battery aging and degrade battery capacity.

Optionally in some examples, including in at least one preferred example, the processing circuitry is further configured to store the measured discharged energy discharged from the battery in the discharge mode, and store the measured charge energy delivered to the battery in the charge mode. A technical benefit may be to retain the measured discharged energy to be used to perform battery health analyses and/or accurately calibrate the battery SOC estimation system used to indicate battery SOC remaining for a user to make charging decisions.

Optionally in some examples, including in at least one preferred example, the processing circuitry is further configured to calibrate battery SOC estimation system based on at least one of the measured discharged energy discharged from the battery in the discharge mode, and the measured charge energy delivered to the battery in the charge mode. A technical benefit may be using the measured discharged energy to more accurately calibrate the battery SOC estimation system used to indicate battery SOC remaining for a user to make charging decisions.

Optionally in some examples, including in at least one preferred example, the processing circuitry is further configured to schedule the discharge/charge operational mode based on a time-of-day (TOD) schedule. A technical benefit may be performing the charging cycle(s) at times when power is less expensive and/or in lower demand, and performing the discharging cycle(s) at times when power is more expensive and/or in higher demand.

Optionally in some examples, including in at least one preferred example, the processing circuitry is further configured to communicate the discharge request at a first scheduled time based on a higher cost energy rate of a time-of-day (TOD) schedule, and communicate the charge request at a second scheduled time based on a lower cost energy rate of a TOD schedule, wherein the lower cost energy rate is lower than the higher cost energy rate. A technical benefit may be performing the charging cycle(s) at times when power is less expensive and/or in lower demand, and performing the discharging cycle(s) at times when power is more expensive and/or in higher demand.

Optionally in some examples, including in at least one preferred example, the processing circuitry is further configured to communicate the discharge request at a first scheduled time based on a higher energy demand of a time-of-day (TOD) schedule, and communicate the charge request at a second scheduled time based on a lower energy demand of a TOD schedule, wherein the lower energy demand is lower than the higher energy demand. A technical benefit may be performing the charging cycle(s) at times when power is in lower demand, and performing the discharging cycle(s) at times when power is in higher demand to alleviate stress on the power grid.

Optionally in some examples, including in at least one preferred example, a vehicle that includes the computer system described above is provided. A technical benefit may include the vehicle being able to electronically request performance of the discharge/charge cycle through a connected charging station capable of charging and discharging its battery, as discharging times may also be faster than can be performed by activation of on-board power-consuming devices in the EV. Also, by the EV being able to request performance of the discharge/charge cycle through a connected charging station, energy that is discharged from the EV battery can be conserved by being transferred back to the power grid.

According to a second aspect of the disclosure, a computer-implemented method including receiving, by processing circuitry of a computer system, a request for a vehicle to enter a discharge/charge operational mode while a vehicle charging port of the vehicle is coupled to an external charging station configured to operate in a vehicle-to-grid (V2G) mode is disclosed. In response to the request for the vehicle to enter the discharge/charge operational mode, the method further includes deactivating, by the processing circuitry of the computer system, power consuming devices in the vehicle not essential to the vehicle operating in the discharge/charge operational mode; communicating, by the processing circuitry of the computer system, a discharge request to the external charging station to discharge energy from a battery in the vehicle to a power grid coupled to the external charging station at a first steady state current in a discharge mode; measuring, by the processing circuitry of the computer system, the discharged energy from the battery in the discharge mode; and detecting, by the processing circuitry of the computer system, the battery at a first predetermined lower voltage in the discharge mode. In response to detecting the battery at the first predetermined lower voltage in the discharge mode, the method further includes communicating, by the processing circuitry of the computer system, a charge request to the external charging station to deliver charge energy to the battery from the power grid at a second steady state current in a charge mode; and measuring, by the processing circuitry of the computer system, the charge energy delivered to the battery in the charge mode. A technical benefit may include an EV being able to electronically request performance of the discharge/charge cycle through a connected charging station capable of charging and discharging its battery, as discharging times may also be faster than can be performed by activation of on-board power-consuming devices in the EV. Also, by the EV being able to request performance of the discharge/charge cycle through a connected charging station, energy that is discharged from the EV battery can be conserved by being transferred back to the power grid.

Optionally in some examples, including in at least one preferred example, a computer program project including program code for performing, when executed by processing circuitry, the above method discussed above is disclosed. A technical benefit may include an EV that executes the program code being able to electronically request performance of the discharge/charge cycle through a connected charging station capable of charging and discharging its battery, as discharging times may also be faster than can be performed by activation of on-board power-consuming devices in the EV. Also, by the EV being able to request performance of the discharge/charge cycle through a connected charging station, energy that is discharged from the EV battery can be conserved by being transferred back to the power grid.

Optionally in some examples, including in at least one preferred example, a non-transitory computer-readable storage medium including instructions, which when executed by processing circuitry, cause the processing circuitry to perform the method discussed above is disclosed. A technical benefit may include an EV that has transitory computer-readable storage medium including instructions to be able to electronically request performance of the discharge/charge cycle through a connected charging station capable of charging and discharging its battery, as discharging times may also be faster than can be performed by activation of on-board power-consuming devices in the EV. Also, by the EV being able to request performance of the discharge/charge cycle through a connected charging station, energy that is discharged from the EV battery can be conserved by being transferred back to the power grid.

The disclosed aspects, examples (including any preferred examples), and/or accompanying claims may be suitably combined with each other as would be apparent to anyone of ordinary skill in the art. Additional features and advantages are disclosed in the following description, claims, and drawings, and in part will be readily apparent therefrom to those skilled in the art or recognized by practicing the disclosure as described herein.

There are also disclosed herein computer systems, control units, code modules, computer-implemented methods, computer readable media, and computer program products associated with the above discussed technical benefits.

### BRIEF DESCRIPTION OF THE DRAWINGS

Examples are described in more detail below with reference to the appended drawings.

FIG. 1 is an exemplary electric vehicle (EV) that has an on-board computer system configured to configure measure battery capacity of a battery through a vehicle-to-grid (V2G) discharge and charge cycling operation through a charging station configured to operate in a V2G mode;

FIG. 2 is a schematic diagram of an exemplary EV charging system that includes an exemplary EV with a computer system configured to perform a discharge/charge cycle in a discharge/charge operational mode to discharge and charge a battery in the EV through a connected charging station configured to operate in a V2G mode while measuring the discharge energy from the battery from discharging, and measuring the charge energy delivered to the battery from charging;

FIG. 3A is a flowchart illustrating an exemplary discharge/charge process of the computer system in the EV in FIG. 2 controlling a discharge/charge cycle in a discharge/charge operational mode to discharge the battery in a discharge mode through a connected charging station operating in a V2G mode while measuring the discharge energy from the battery, and then controlling the discharge/charge cycle to charge the battery from the charging station in a charge mode while measuring the charge energy delivered to the battery;

FIG. 3B is a flowchart illustrating another exemplary discharge/charge process of the computer system in the EV in FIG. 2 controlling a discharge/charge cycle in a discharge/charge operational mode to discharge the battery in a discharge mode through a connected charging station operating in a V2G mode while measuring the discharge energy from the battery, and then controlling the discharge/charge cycle to charge the battery from the charging station in a charge mode while measuring the charge energy delivered to the battery;

FIG. 4 is a flowchart illustrating another exemplary discharge/charge process of the computer system in the EV in FIGS. 1 and 2 that includes initially charging the battery from the connected charging station, and then performing the discharge/charge processes in FIG. 3A or 3B;

FIGS. 5A and 5B is an exemplary communication flow/process illustrating an exemplary discharge/charge process of the computer system in the EV in FIGS. 1 and 2 controlling a discharge/charge cycle in a discharge/charge operational mode to discharge the battery in a discharge mode through a connected charging station operating in a V2G mode while measuring the discharge energy from the battery, and then controlling the discharge/charge cycle to charge the battery from the charging station in a charge mode while measuring the charge energy delivered to the battery;

FIG. 6 is a flowchart illustrating another exemplary discharge/charge process of the computer system in the EV in FIGS. 1 and 2 that includes initially charging the battery from the connected charging station, and then performing the discharge/charge process in FIGS. 5A and 5B; and

FIG. 7 is a block diagram of an exemplary computer system that can be included in a vehicle, including, but not limited to, the computer system in FIGS. 1 and 2, to perform a discharge/charge cycle in a discharge/charge operational mode to discharge and charge a battery in the EV through a connected charging station configured to operate in a V2G mode.

### DETAILED DESCRIPTION

The detailed description set forth below provides information and examples of the disclosed technology with sufficient detail to enable those skilled in the art to practice the disclosure.

Aspects disclosed herein involve measuring battery capacity of a battery installed on a vehicle through a vehicle-to-grid (V2G) discharge and charge cycling operation. The vehicle is an electric vehicle (EV) in that it includes an installed battery (ies) to provide a power source for operation. For example, the EV could be a battery EV (BEV) or plug-in hybrid EV (PHEV) that has the capability of recharging its battery (ies) from an external charging source (e.g., a charging station). To determine the actual battery capacity of the battery (ies), the EV can be configured to be put into a discharge/charge operational mode to perform a discharge/charge cycle to fully charge and discharge the battery. During the charging time, the energy transferred to the battery is measured (e.g., by integrating power transfer) to provide an accurate battery capacity of the battery available for energy storage and discharge. In exemplary aspects, the EV is configured to perform the discharge/charge cycle in the discharge/charge operational mode cooperatively through a power connection to a charging station that is configured to operate in a V2G mode. In this regard, the charging station is not only controllable by the EV to charge its battery from grid power, but the charging station is also controllable by the EV to discharge energy from its battery back to the grid in a V2G operation mode. For example, the charging station may be compatible with a V2G operational standard or specification that allows for EV batteries to be charged to store excess energy from the power grid and then be discharged back to the power grid at higher energy demand to ease pressure on the power grid infrastructure. By the EV being able to electronically request performance of the discharge/charge cycle through a connected charging station capable of charging and discharging its battery, discharging times may also be faster than can be performed by activation of on-board power-consuming devices in the EV. Also, by the EV being able to request performance of the discharge/charge cycle through a connected charging station, energy that is discharged from the EV battery can be conserved by being transferred back to the power grid.

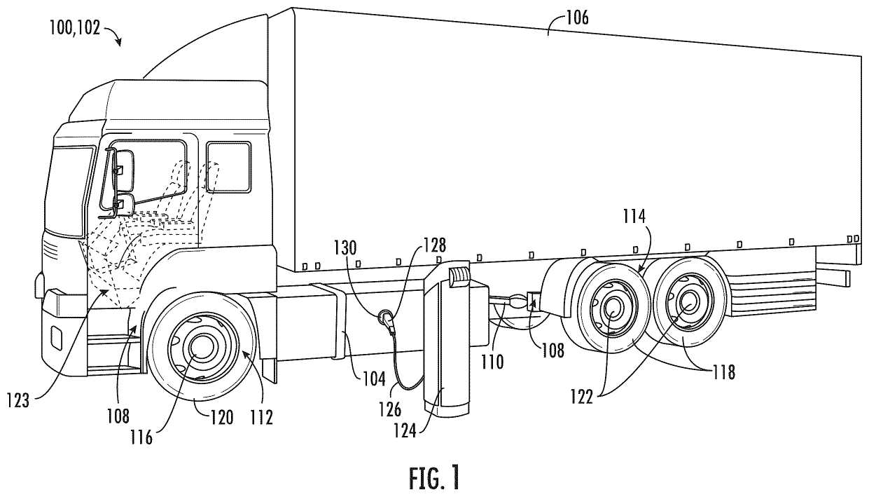

In this regard, FIG. 1 is an exemplary vehicle 100 that is an EV 102. In this example, the EV 102 is a BEV that is exclusively powered by electrical energy from an on-board battery 104. In FIG. 1, the EV 102 is shown coupled to a trailer 106. The EV 102 includes one or more electric motors 108 that are coupled to one or more respective drive shafts 110 that are the front and rear axles 112, 114. The rotation of the drive shafts 110 will cause the power of the electric motors 108 to be transferred to the axles 112, 114 to rotate front and rear tires 116, 118 mounted on respective wheels 120, 122. In this example, the EV 102 is also equipped to be operated in four-wheel drive (4WD), wherein separate electric motors 108 powered by the battery 104 are coupled to the respective front and rear axles 112, 114 causing the front wheels 120 and their mounted tires 116 to rotate. The EV 102 is also configured to power other power-consuming devices 123 from power in the battery 104. For example, the other power-consuming devices 123 may include computerized displays, heating and air conditioning systems, audio equipment, and external and internal lights, as non-limiting examples.

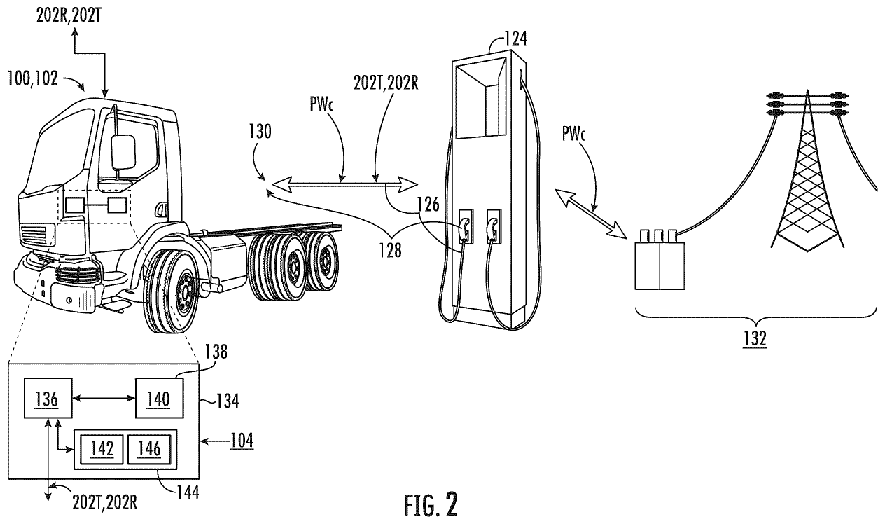

As shown in FIG. 1, the EV 102 has the on-board battery 104 that is configured to store electrical energy from recharging and release the stored electric energy to operate the electric motors 108. FIG. 1 shows the EV 102 being stationary and its battery 104 being charged through a coupled external charging station 124. The charging station 124 has a charging cable 126 with a connector 128 on the end that is configured to be physically and electrically coupled to a vehicle charging port 130 on the EV 102. As shown in FIG. 1 and also shown in FIG. 2, when the charging station 124 is placed in a charging mode, the charging station 124 draws power via a charging power signal PWc from a connected power grid 132 to transfer the received power through the charging cable 126 to the battery 104 to charge the battery 104. A power grid 132 is a power delivery infrastructure that includes not only a power source for the power grid 132, but transmission lines and transmission stations as well as last mile power lines to power equipment, such as transformers. When it is desired to no longer charge the battery 104, the connector 128 of the charging cable 126 can be decoupled (i.e., disconnected) from the vehicle charging port 130 on the EV 102.

As shown in FIG. 2, the EV 102 has an on-board computer system 134 (e.g., an electronic control unit (ECU)) which includes processing circuitry 136, such as a microcontroller or microprocessor. The on-board computer system 134 is powered by the battery 104. The on-board computer system 134 is configured to measure battery capacity of the on-board battery 104 that represents a state-of-charge (SOC) of the battery 104 (also referred to as “battery SOC”). The SOC of the battery 104 is the remaining amount of energy in the battery 104 at a specific point in time available to be discharged to provide power to a coupled power-consuming device(s), such as the electric motors 108 and/or other power-consuming devices in the EV 102. The computer system 134 may be equipped with an on-board battery SOC estimation system 138 (e.g., that includes another computer system with processing circuitry 140, such as a microprocessor(s) and/or microcontroller(s)) that is configured to perform a battery SOC estimation algorithm (e.g., by executing computer instructions according to the battery SOC estimation algorithm) to estimate the SOC based on an estimation of power consumed during operation and driving of the EV 102. The on-board battery SOC estimation system 138 may also be configured to provide a visual indication of the SOC of the battery 104 to a driver of the EV 102 as a percentage of stored energy as compared to the maximum storage capacity of the battery 104 and/or as an estimated travel distance (e.g., in kilometers or miles). In this manner, the driver of the vehicle can use the visual indication of the SOC of the battery 104 to determine when recharging of the battery 104 may be desired and/or for other trip planning and routing purposes. The on-board computer system 134 may also be configured to operate the EV 102 and/or provide other services based on the SOC of the battery 104 determined by the on-board battery SOC estimation system 138. For example, the determined SOC of the battery 104 may be used by the on-board computer system 134 to control regenerative braking. For example, if the battery 104 has a higher SOC over a defined threshold, there may not be enough available storage capacity in the battery 104 to store energy generated as a result of regenerative braking. As another example, the determined SOC of the battery 104 may be used by the on-board computer system 134 for trip planning and routing to ensure that the vehicle can complete its trip on available power stored in the battery 104 and/or to suggest charging stops to the driver.

Even with the EV 102 being equipped with the computer system 134 that is capable of estimating the SOC of the battery 104, the battery SOC estimation algorithm may become less accurate over time after a large number of charges and discharges due to the aging of the battery 104, known as “capacity fade.” The aging of the battery 104 can cause a gradual decrease in the battery's 104 ability to store and deliver charge over time, thus causing assumptions about how charging will affect the battery SOC to be less accurate. A full discharge/charge cycle of the battery 104 provides more data points for accurate calibration and adjustment of the battery SOC estimation algorithm. Thus, it may still be necessary to periodically determine the exact battery capacity of the battery 104 even with the on-board battery SOC estimation system 138. For example, a technician can be called out to the location of the EV 102 to perform the full discharge and charge cycle on its battery 104 on site to determine the true battery capacity of the battery 104. In this manner, if the true battery capacity of the battery 104 has degraded below a desired or necessary capacity, the battery 104 can be repaired (by replacing bad cells) or replaced. The way to truly measure battery capacity of the battery 104 is to fully discharge the battery 104 followed by a full charging of the battery 104 back to a full charge. During the charging time, the energy transferred to the battery 104 can be measured (e.g., by integrating power transfer) to provide an accurate, current battery capacity of the battery 104 available for energy storage and discharge. The actual battery capacity of the battery 104 can then be reported by the computer system 134 and/or the on-board battery SOC estimation system 138 for decisions about battery 104 repair and/or replacement, if needed. The measured transfer energy can also be used to recalibrate settings for a battery SOC estimation algorithm for correlating charging to the SOC of the battery 104.

As discussed in more detail below, to provide for the computer system 134 and/or the on-board battery SOC estimation system 138 to determine the actual battery capacity of the battery 104, the EV 102 can be configured to be put into a discharge/charge operational mode to perform a discharge/charge cycle to fully charge and discharge the battery 104. The computer system 134 and/or its processing circuitry 136 can be configured to set an operational mode indicator 142 (e.g., a memory register) in a memory 144 in the computer system 134 when the EV 102 is put into a discharge/charge operational mode. For example, the operational mode indicator 142 could be a memory word that includes either that the EV 102 is in a non-charge mode (e.g. ‘0x00’ bits), the EV 102 is in a discharge mode (e.g. ‘0x01’ bits), the EV 102 is in a charge mode (e.g. ‘0x10’ bits), or the EV 102 is in an initial charge mode (e.g. ‘0x11’ bits), which are discussed in more detail below. This is so that the computer system 134 and/or its processing circuitry 136 can track the operational mode during operations performed in the discharge/charge cycle of the EV 102 as discussed in more detail below. The computer system 134 and/or its processing circuitry 136 can also be configured to store a measured amount of energy discharged and/or charged from the battery 104 in an energy measurement indicator 146 in the memory 144 for access by the computer system 134 and/or its processing circuitry 136 or the on-board battery SOC estimation system 138.

During the charging time in a charge mode, the energy transferred to the battery 104 is measured (e.g., by integrating power transfer) to provide an accurate battery capacity of the battery 104 available for energy storage and discharge. In exemplary aspects, the EV 102 (or its computer system 134 and/or the on-board battery SOC estimation system 138) is configured to perform the discharge/charge cycle for the battery 104 in the discharge/charge operational mode cooperatively through the power connection to the charging station 124 that is configured to operate in a V2G mode. In this example, the charging station 124 is compatible with the V2G operation that allows energy to be transferred back (i.e., pushed back) to its connected power grid 132 from the battery 104 of the EV 102. For example, when it is stated that energy is transferred back to the power grid 132, it is understood that the discharge energy from the battery 104 transferred by the charging station 124 to the power grid 132 may be delivered to a next closest power consuming facility to the charging station 124 also coupled to the power grid 132 based on the principle of energy flowing to the path of least resistance. In this manner, the charging station 124 can be used in a discharge mode while connected to the EV 102 to provide a discharge path for discharging energy stored in the battery 104 without such discharge energy having to be lost through consumption by activated on-board power-consuming devices in the EV 102 and/or in the form of heat dissipation from energy losses. The charging station 124 compatible with V2G operation also allows for EV batteries, such as the battery 104 of the EV 102, to be charged to store excess energy from the power grid 132 at times of lower energy demand and then be discharged back to the power grid 132 during times of higher energy demand to ease pressure on the power infrastructure of the power grid 132.

Thus, in this example, the charging station 124 is not only controllable by the EV 102 to charge its battery 104 from the power grid 132 connected to the charging station 124, but the charging station 124 is also controllable by the EV 102 to discharge energy from its battery 104 back to the power grid 132 in a V2G operation mode. By the EV 102 being able to electronically request performance of the discharge/charge cycle through the connected charging station 124 capable of charging and discharging its battery 104, discharging times may also be faster than can be performed by activation of on-board power-consuming devices in the EV 102. Also, by the EV 102 being able to request performance of the discharge/charge cycle through the connected charging station 124, energy that is discharged from the battery 104 of the EV 102 can be conserved by being transferred back to the power grid 132 via the charging station 124 being configured for V2G charging/discharging.

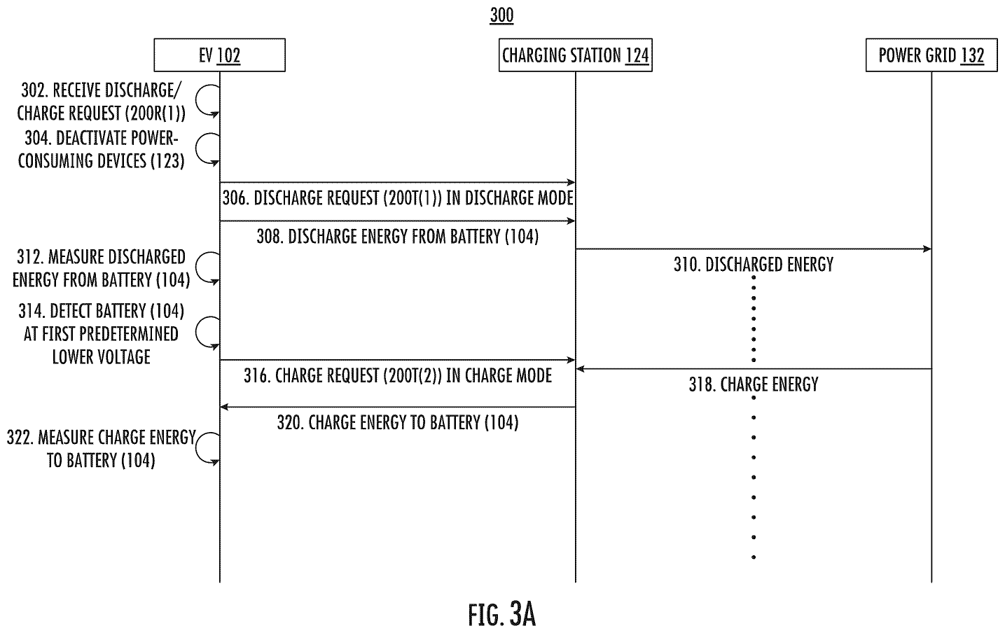

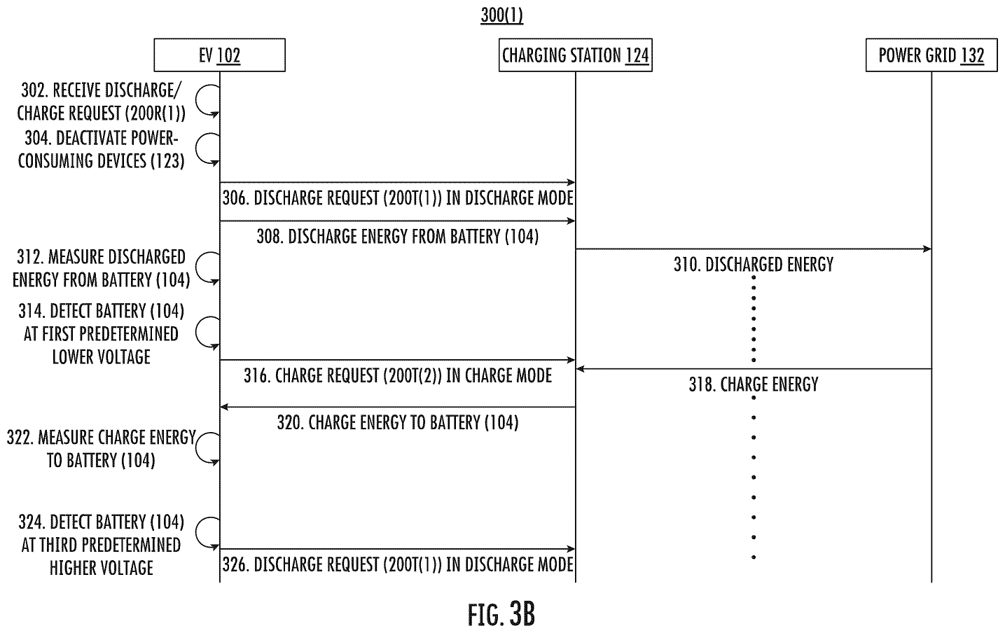

FIG. 3A is a flowchart illustrating an exemplary discharge/charge process 300 of the computer system 134 and/or the on-board battery SOC estimation system 138 in the EV 102 in FIGS. 1 and 2 controlling a discharge/charge cycle in a discharge/charge operational mode. The discharge/charge process 300 in FIG. 3A is discussed with reference to the exemplary EV 102 and charging station 124 in FIG. 2. As discussed in more detail below, the computer system 134 and/or its processing circuitry 136 in the EV 102 is configured to discharge the battery in a discharge mode through the connected charging station 124 operating in a V2G mode while measuring the discharge energy from the battery 104, and then causing the battery 104 to be charged in a charge mode while measuring the charge energy delivered from the charging station 124 to the battery 104. The EV 102 can use the measured energy transferred during the discharge and charge cycles to determine the battery capacity of its battery 104.

In this regard, as shown in FIG. 3A, the discharge/charge process 300 includes the computer system 134 and/or its processing circuitry 136 receiving a discharge/charge request 200R(1) for the EV 102 to enter a discharge/charge operational mode while the vehicle charging port 130 of the EV 102 is coupled to the charging station 124 configured to operate in a V2G mode (block 302 in FIG. 3A). For example, the EV 102 may have a user interface that can communicate the discharge/charge request 200R(1) to the computer system 134 and/or its processing circuitry 136 in response to a technician requesting the EV 102 be placed in a discharge/charge operational mode to perform a discharge/charge process 300 in order to determine the battery capacity of the battery 104. Alternatively, the EV 102 may be configured to receive a remote communication, such as over the charging cable 126 as a received communication signal 200R as shown in FIG. 2 or through a received wireless telemetry signal 202R, to receive the discharge/charge request 200R(1) to cause the computer system 134 to perform the discharge/charge process 300. This may be advantageous if it is desired to avoid the need for a technician to have to be dispatched to the location of the EV 102 to request the EV 102/computer system 134 to perform the to perform the discharge/charge process 300.

Then, with continuing reference to FIG. 3A, in response to the request for the EV 102 to enter the discharge/charge operational mode to perform the discharge/charge process 300 in step 302, the computer system 134 and/or its processing circuitry 136 is configured to deactivate (e.g., turn off, idle) power-consuming devices 123 in the EV 102 that are not essential to the EV 102 operating in the discharge/charge operational mode (block 304 in FIG. 3A). This is so that other power-consuming devices 123 that are not essential to the EV 102 operating in the discharge/charge operational mode in the discharge/charge process 300 do not consume power from the battery 104. Otherwise, it may not be possible to obtain an accurate capacity of the battery 104 in the EV 102 since, as discussed below, the rate of discharge and charge of the battery 104 and the power discharged and consumed from discharging and charging is used to determine the capacity of the battery 104.

Then, with continuing reference to FIG. 3A, after the power-consuming devices 123 in the EV 102 that are not essential to the EV 102 operating in the discharge/charge operational mode are de-activated (block 304 in FIG. 3A), the computer system 134 and/or its processing circuitry 136 is then configured to communicate a discharge request 200T(1) in a discharge mode to the charging station 124 to discharge energy from the battery 104 in the EV 102 to the power grid 132 coupled to the charging station 124 (block 306 in FIG. 3A). The computer system 134 and/or its processing circuitry 136 may be configured to store a discharge mode in the operational mode indicator 142 in response to receiving the discharge request 200T(1). In this example, to determine the capacity of the battery 104, the battery 104 is discharged so that when the battery 104 is subsequently charged, the battery 104 is charged from a known SOC to allow a more accurate determination of the capacity of the battery 104. The discharge request 200T(1) can be part of a transmission signal 200T communicated from the EV 102 over the charging cable 126 to the charging station 124 as shown in FIG. 2 as an example. In response to the charging station 124 receiving the discharge request 200T(1) in the discharge mode, the charging station 124 is configured to discharge energy from the battery 104 of the EV 102 through the charging cable 126 (block 308 in FIG. 3A and also see FIG. 2). The discharged energy from the battery 104 that is transferred to and received by the charging station 124 can be transferred to the power grid 132 (block 310 in FIG. 3A). In an example, in the discharge mode, the EV 102 may be configured to communicate the discharge request 200T(1) to the charging station 124 to instruct the charging station 124 to discharge energy from the battery 104 of the EV 102 at a first steady state current (e.g., between 5 Amps (A) and 50 A). In this manner, it may be possible for the computer system 134 and/or its processing circuitry 136 to more accurately measure the discharged energy from the battery 104.

Then, with continuing reference to FIG. 3A, in the discharge mode as the energy from the battery 104 is discharged by the charging station 124 (block 308 in FIG. 3A), the computer system 134 and/or its processing circuitry 136 is configured to measure the discharged energy from the battery 104 (block 312 in FIG. 3A). For example, the computer system 134 and/or its processing circuitry 136 can be configured to measure the discharged energy from the battery 104 by integrating the instantaneous discharged energy from the battery 104 to the charging station 124. The computer system 134 and/or its processing circuitry 136 may be configured to store the measured discharged energy from the battery 104 in the discharge mode in the EV 102. The computer system 134 and/or its processing circuitry 136 continues in the discharge mode until the battery 104 is detected to be at a first predetermined lower voltage (e.g., less than 610-620 Volts (V) in an 800 V charging system) indicative of the battery 104 being fully discharged or sufficiently discharged before beginning a charge cycle (block 314 in FIG. 3A).

In response to detecting the battery 104 at the first predetermined lower voltage in the discharge mode (block 314 in FIG. 3A), the computer system 134 and/or its processing circuitry 136 is then configured to communicate a charge request 200T(2) to the charging station 124 in a charge mode (block 316 in FIG. 3A). The computer system 134 and/or its processing circuitry 136 may be configured to store a charge mode in the operational mode indicator 142 in response to receiving the charge request 200T(2). The computer system 134 and/or its processing circuitry 136 may be configured to wait for a predetermined amount of time before communicating the charge request 200T(2) to the charging station 124 after detecting the battery 104 to be at the first predetermined lower voltage in the discharge mode (block 314 in FIG. 3A) to allow the energy stored in cells of the battery 104 to balance. The charge request 200T(2) can be part of a transmission signal 200T communicated from the EV 102 over the charging cable 126 to the charging station 124 as shown in FIG. 2 as an example. This causes the charging station 124 to transfer energy received from the power grid 132 (block 318 in FIG. 3A) to the battery 104 over the charging cable 126 (block 320 in FIG. 3A) to charge the battery 104. In an example, in the charge mode, the EV 102 may be configured to communicate the charge request 200T(2) to the charging station 124 to instruct the charging station 124 to deliver charge energy to the battery 104 of the EV 102 at a second steady state current (e.g., between 5 A and 50 A). In this manner, it may be possible for the computer system 134 and/or its processing circuitry 136 to more accurately measure the charge energy delivered to the battery 104.

In the charge mode, as the received charge energy charges the battery 104, the computer system 134 and/or its processing circuitry 136 is configured to measure the charge energy delivered to the battery 104 (block 322 in FIG. 3A). For example, the computer system 134 and/or its processing circuitry 136 can be configured to measure the charged energy delivered to the battery 104 by integrating the instantaneous charge delivered to the battery 104 from the charging station 124. The computer system 134 and/or its processing circuitry 136 may be configured to store the measured charge energy delivered to the battery 104 in the charge mode in the EV 102 in the energy measurement indicator 146 in the memory 144.

FIG. 3B is a flowchart illustrating another exemplary discharge/charge process 300(1) of the computer system 134 and/or the on-board battery SOC estimation system 138 in the EV 102 in FIGS. 1 and 2 controlling a discharge/charge cycle in a discharge/charge operational mode. The discharge/charge process 300(1) in FIG. 3B is discussed with reference to the exemplary EV 102 and charging station 124 in FIG. 2. The discharge/charge process 300(1) in FIG. 3B includes the same steps 302-322 as in the discharge/charge process 300 in FIG. 3A.

In the discharge/charge process 300(1) in FIG. 3B, the computer system 134 and/or its processing circuitry 136 continues in the charge mode (e.g., as indicated in the operational mode indicator 142) until the battery 104 is detected to be at a second predetermined higher voltage (e.g., 710-720 V in an 800 V charging system) indicative of the battery 104 being fully charged or sufficiently charged (block 324 in FIG. 3B). The battery 104 being at the second predetermined higher voltage is an indication of the battery 104 being fully charged or sufficiently charged such that the measured charge energy is an indication of the capacity of the battery 104. In response to detecting the battery 104 at the second predetermined higher voltage (block 324 in FIG. 3B), the computer system 134 and/or its processing circuitry 136 is configured to disable the discharge/charge mode by communicating a discharge/charge mode request 200T(3) to the charging station 124 to discontinue charging (block 326 in FIG. 3B).

In any of the aforementioned processes or otherwise in another discharge/charge process, the EV 102 and/or its computer system 134 or its processing circuitry 136, or the on-board battery SOC estimation system 138 can use the measured energy (e.g., stored in the energy measurement indicator 146 in the memory 144) transferred during the discharge and charge cycles with the battery 104 in either the discharge/charge processes 300, 300(1) in FIGS. 3A and 3B to determine the battery capacity of the battery 104. The measured discharge and charge energy can be displayed to a technician or an operator of the EV 102. The technician or operator of the EV can use the determined battery capacity of the battery 104 of the EV 102 to determine if the battery 104 should be repaired or replaced. Also, the determined battery capacity of the battery 104 can be used by the EV 102 to update the battery SOC estimation system 138 and algorithm so that a more accurate SOC can be determined and/or displayed to the operator of the EV 102.

Also, by the EV 102 being able to electronically request performance of the discharge/charge cycle through a connected battery charging station 124 capable of charging and discharging its battery 104, the EV 102 can be scheduled and/or controlled, including remotely controlled, to perform the discharge/charge process 300 at any time when connected to the charging station 124 without the need for human action or intervention. In another exemplary aspect, the EV 102 can be configured to initiate the discharge/charge operational mode with the connected charging station 124 to determine the battery capacity of its battery 104 based on a certain scheduled time in a time-of-day (TOD) schedule that has information on varying power rates based on TOD which may be based on energy demand on the power grid 132. For example, when TOD power rates are higher and/or energy demand on the power grid 132 is higher, the EV 102 can be configured to perform a discharge cycle of the battery 104 in the discharge mode to transfer energy back to the power grid 132. This provides more energy on the power grid 132 to help supply higher energy demand and/or may entitle the EV 102 to a higher power transfer credit when energy rates are higher. In the converse, the EV 102 can also be configured to perform a charge cycle of the battery 104 in the charge mode to receive transferred energy from the power grid 132 to charge the battery 104 when TOD power rates are lower and/or energy demand on the power grid 132 is reduced. This causes energy to be transferred from the power grid 132 when energy demand is lower and when energy rates are less expensive.

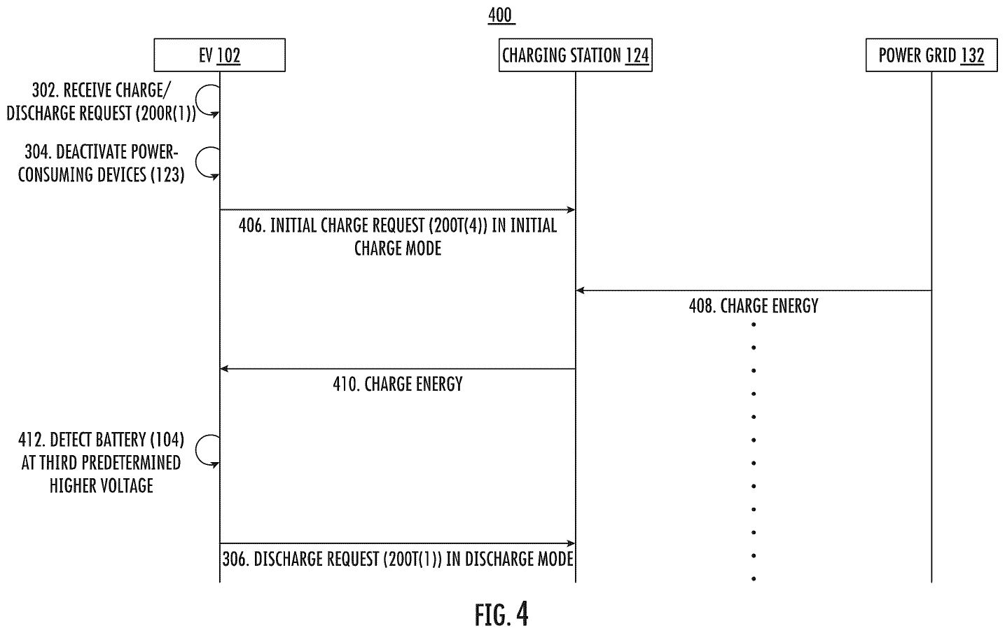

Note that the EV 102 can also be configured in the discharge/charge operational mode to first optionally request that the connected charging station 124 charge the battery 104 from power from the power grid 132 delivered through the charging station 124 in an initial charge mode before a discharge mode is performed. This is shown in the exemplary alternative discharge/charge process 400 for the EV 102 in FIG. 4 that includes initially charging the battery 104 from the connected charging station 124, before performing the discharge/charge processes 300 or 300(1) in FIGS. 3A and 3B.

The discharge/charge process 400 in FIG. 4 is discussed with reference to the exemplary EV 102 and charging station 124 in FIG. 2. As discussed in more detail below, the computer system 134 and/or the on-board battery SOC estimation system 138 in the EV 102 is configured to discharge the battery 104 in a discharge mode through the connected charging station 124 operating in a V2G mode while measuring the discharge energy from the battery 104, and then cause the battery 104 to be charged in a charge mode while measuring the charge energy delivered from the charging station 124 to the battery 104. The EV 102 can use the measured energy transferred during the discharge and charge cycles to determine the battery capacity of its battery 104.

In this regard, as shown in FIG. 4, the alternative discharge/charge process 400 includes the computer system 134 and/or its processing circuitry 136 receiving a discharge/charge request 200R(1) for the EV 102 to enter a discharge/charge operational mode while the vehicle charging port 130 of the EV 102 is coupled to the charging station 124 configured to operate in a V2G mode (block 302 in FIG. 4). Then, in response to the request for the EV 102 to enter the discharge/charge operational mode to perform the discharge/charge process 400 in step 302, the computer system 134 and/or its processing circuitry 136 deactivates (e.g., turn off, idle) power-consuming devices 123 in the EV 102 that are not essential to the EV 102 operating in the discharge/charge operational mode (block 304 in FIG. 4). This has been previously described in the discharge/charge processes 300 or 300(1) in FIGS. 3A and 3B.

With continuing reference to FIG. 4, instead of communicating the discharge request 200T(1) to the charging station 124 as discussed in block 306 in the discharge/charge processes 300, 300(1) in FIGS. 3A and 3B, the computer system 134 and/or its processing circuitry 136 instead communicates an optional initial charge request 200T(4) to the charging station 124 in an initial charge mode (block 406 in FIG. 4). The computer system 134 and/or its processing circuitry 136 may be configured to store an initial charge mode in the operational mode indicator 142 in response to receiving the discharge request 200T(4). The initial charge request 200T(4) can be part of a transmission signal 200T communicated from the EV 102 over the charging cable 126 to the charging station 124 as shown in FIG. 2 as an example. This causes the charging station 124 to transfer energy received from the power grid 132 (block 408 in FIG. 4) to the battery 104 over the charging cable 126 (block 410 in FIG. 4) to initially charge the battery 104. In an example, in the initial charge mode, the EV 102 communicates the initial charge request 200T(4) to the charging station 124 to instruct the charging station 124 to deliver charge energy to the battery 104 of the EV 102 at a third current (e.g., which may be a steady state and may also be between 5 A and 50 A).

The computer system 134 and/or its processing circuitry 136 continues in the initial charge mode until the battery 104 is detected to be at a third predetermined higher voltage (e.g., 710-720 V in an 800 V nominal voltage charging system) indicative of the battery 104 being fully charged or sufficiently charged (block 412 in FIG. 4). In response to detecting the battery 104 at the third predetermined higher voltage (block 412 in FIG. 4), the computer system 134 and/or its processing circuitry 136 enters into the discharge mode by communicating the discharge request 200T(1) to the charging station 124 to discharge the battery 104 as shown in block 306 in FIGS. 3A and 3B. The computer system 134 and/or its processing circuitry 136 may be configured to store a discharge mode in the operational mode indicator 142 in response to receiving the discharge request 200T(1). The remainder of this alternative discharge/charge process 400 can be performed starting at block 306 in FIGS. 3A and 3B and continuing to block 326 in the discharge/charge process 300(1) in FIG. 3B just as described above.

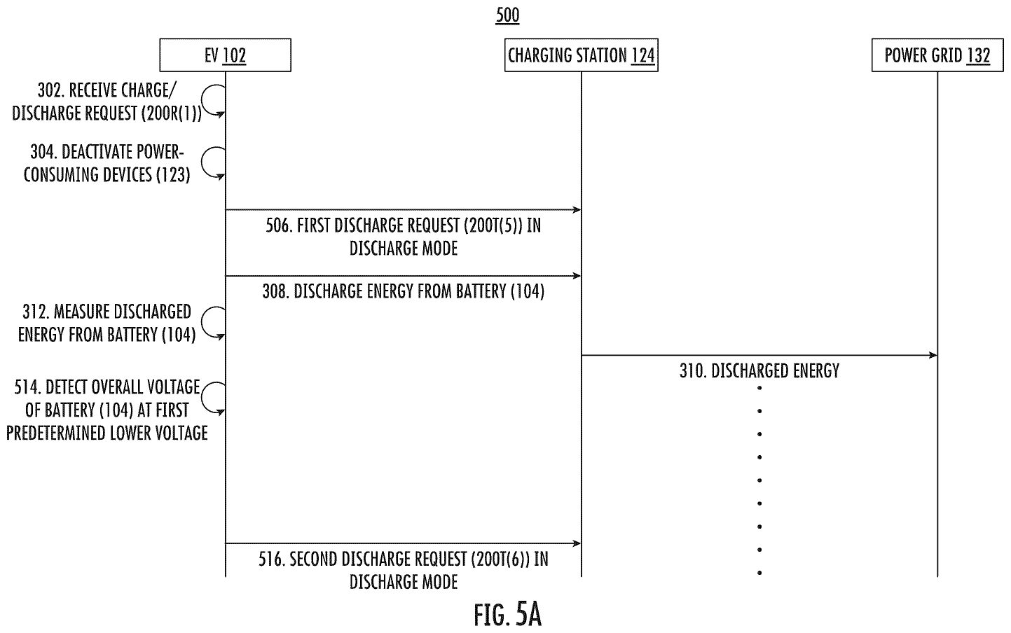

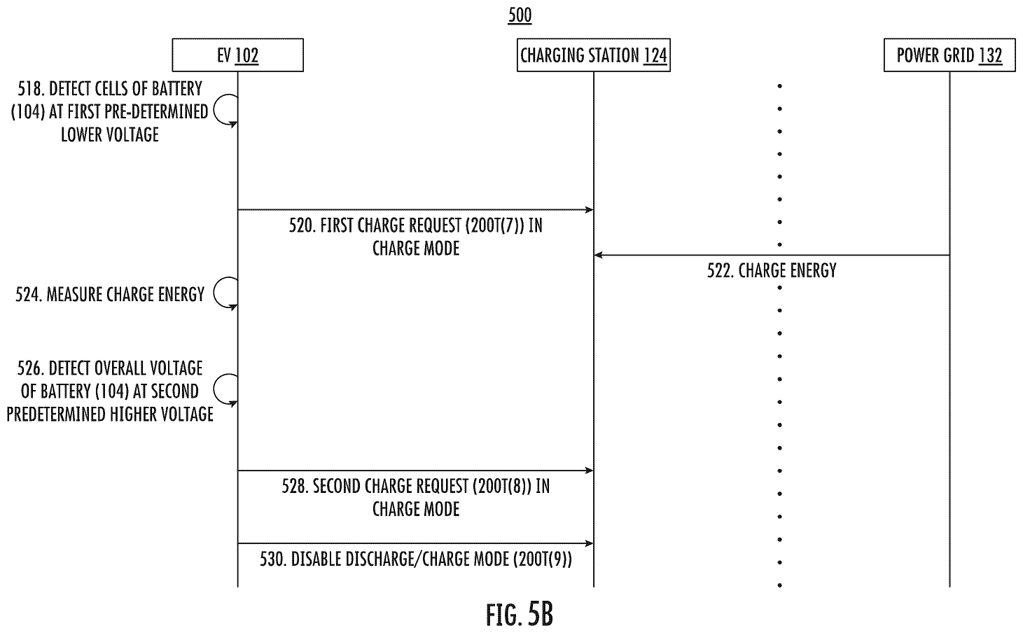

FIGS. 5A and 5B are a flowchart illustrating another exemplary discharge/charge process 500 of the computer system 134 and/or the on-board battery SOC estimation system 138 in the EV 102 in FIGS. 1 and 2 controlling a discharge/charge cycle in a discharge/charge operational mode. As discussed in more detail below, the discharge/charge process 500 in FIGS. 5A and 5B is similar to the discharge/charge processes 300, 300(1) in FIGS. 3A and 3B, however, the discharge/charge process 500 involves using multiple current levels in both the discharging and charging of the battery 104 to achieve faster discharging and charging times, while avoiding excesses energy losses and battery 104 degradation when the battery 104 is near a full charge. The discharge/charge process 500 in FIGS. 5A and 5B is discussed with reference to the exemplary EV 102 and charging station 124 in FIG. 2. Like the discharge/charge processes 300, 300(1) in FIGS. 3A and 3B, the discharge/charge process 500 in FIGS. 5A and 5B involves the computer system 134 and/or its processing circuitry 136 in the EV 102 discharging the battery 104 in a discharge mode through the connected charging station 124 operating in a V2G mode while measuring the discharge energy from the battery 104, and then causing the battery 104 to be charged in a charge mode while measuring the charge energy delivered from the charging station 124 to the battery 104. The EV 102 can use the measured energy transferred during the discharge and charge cycles to determine the battery capacity of its battery 104.

In this regard, as shown in FIG. 5A, the discharge/charge process 500 includes the computer system 134 and/or its processing circuitry 136 receiving the discharge/charge request 200R(1) for the EV 102 to enter a discharge/charge operational mode while the vehicle charging port 130 of the EV 102 is coupled to the charging station 124 configured to operate in a V2G mode like in FIGS. 3A and 3B (block 302 in FIG. 5A). Common steps between the discharge/charge process 500 in FIG. 5A and the discharge/charge processes 300, 300(1) in FIGS. 3A and 3B are shown with common block numbers. Then, in response to the request for the EV 102 to enter the discharge/charge operational mode to perform the discharge/charge process 500 in step 302, the computer system 134 and/or its processing circuitry 136 deactivates (e.g., turn off, idle) power-consuming devices 123 in the EV 102 that are not essential to the EV 102 operating in the discharge/charge operational mode like in FIGS. 3A and 3B (block 304 in FIG. 5A).

Then, with continuing reference to FIG. 5A, after the power-consuming devices 123 in the EV 102 that are not essential to the EV 102 operating in the discharge/charge operational mode are de-activated (block 304 in FIG. 5A), the computer system 134 and/or its processing circuitry 136 communicates a first discharge request 200T(5) in a discharge mode to the charging station 124 to discharge energy from the battery 104 in the EV 102 to the power grid 132 coupled to the charging station 124 (block 506 in FIG. 5A). The computer system 134 and/or its processing circuitry 136 may be configured to store the discharge mode in the operational mode indicator 142 in response to receiving the first discharge request 200T(5). The first discharge request 200T(5) requests that the charging station 124 discharge the battery 104 at a first higher steady state current (e.g., 5 A to 50 A) in this example. In this manner, the discharging of the battery 104 can be performed at a faster discharge rate to reduce the overall duration of the discharge/charge process 500. In response to the charging station 124 receiving the first discharge request 200T(5) in the discharge mode, the charging station 124 discharges energy from the battery 104 of the EV 102 through the charging cable 126 (block 308 in FIG. 5A). The discharged energy from the battery 104 that is transferred to and received by the charging station 124 can be transferred to the power grid 132 (block 310 in FIG. 5A). In an example, in the discharge mode, the EV 102 communicates the first discharge request 200T(5) to the charging station 124 to instruct the charging station 124 to discharge energy from the battery 104 of the EV 102 at the first higher steady state current, as a steady state current. In this manner, it may be possible for the computer system 134 and/or its processing circuitry 136 to more accurately measure the discharged energy from the battery 104.

Then, with continuing reference to FIG. 5A, in the discharge mode as the energy from the battery 104 is discharged by the charging station 124 (block 308 in FIG. 5A), the computer system 134 and/or its processing circuitry 136 measures the discharged energy from the battery 104 (block 312 in FIG. 5A). For example, the computer system 134 and/or its processing circuitry 136 can be configured to measure the discharged energy from the battery 104 by integrating the instantaneous discharged energy from the battery 104 to the charging station 124. The computer system 134 and/or its processing circuitry 136 may be configured to store the measured discharged energy from the battery 104 (e.g., in the energy measurement indicator 146 in the memory 144) in the discharge mode in the EV 102. The computer system 134 and/or its processing circuitry 136 continues in the discharge mode until the overall voltage of the battery 104 is detected to be at the first predetermined lower voltage (e.g., less than 610-620 V) indicative of the battery 104 being fully discharged or sufficiently discharged before beginning a charge cycle (block 514 in FIG. 5A).

In response detecting the overall voltage of the battery 104 is at the first predetermined lower voltage in the discharge mode (block 514 in FIG. 5A), the computer system 134 and/or its processing circuitry 136 communicates a second discharge request 200T(6) to the charging station 124 in the discharge mode (block 516 in FIG. 5A) to discharge the battery 104 at a first lower steady state current (e.g., <5A) lower than the first higher steady state current (block 516 in FIG. 5A). The computer system 134 and/or its processing circuitry 136 continues to measure the discharged energy from the battery 104 (block 312 in FIG. 5A). Discharging the battery 104 at the first higher steady state current can achieve a balance between a faster discharge time, while at the same time not discharging energy so fast that excess energy losses are generated by the battery 104 from discharging that can increase battery aging and degrade battery capacity. After the overall voltage of the battery 104 reaches the first predetermined lower voltage, the computer system 134 and/or its processing circuitry 136 requests that the charging station 124 continue discharging the battery 104 at the first lower steady state current until all the battery cells of the battery 104 are within the first predetermined lower voltage (i.e., achieve voltage equalization for a full discharge) (e.g., 3.26 V=620 V/190 battery cells).

Then, as shown in FIG. 5B, the computer system 134 and/or its processing circuitry 136 detects when the cells of the battery 104 are at the first predetermined lower voltage in the discharge mode (i.e., achieve voltage equalization for a full charge) (block 518 in FIG. 5B). This has the advantage of providing an initial fast charging time, but as the SOC of the battery 104 approaches its maximum SOC, the second lower steady state current is used to avoid excess energy resulting in heat generation through losses which can increase battery 104 aging and degrade battery capacity. In response detecting the cells of the battery 104 at the first predetermined lower voltage in the discharge mode (block 518 in FIG. 5B), the computer system 134 and/or its processing circuitry 136 communicates a first charge request 200T(7) to the charging station 124 in a charge mode to charge the battery 104 at a second higher steady state current (e.g., 5 A to 50 A) higher than the first steady state current (block 520 in FIG. 5B). The computer system 134 and/or its processing circuitry 136 may be configured to store the charge mode in the operational mode indicator 142 in response to receiving the first charge request 200T(7). In the charge mode charge energy is delivered to the battery 104 for charging (block 522 in FIG. 5B) from the power grid 132. The computer system 134 and/or its processing circuitry 136 measures the charge energy from the battery 104 (block 524 in FIG. 5B). For example, the computer system 134 and/or its processing circuitry 136 can be configured to measure the charge energy from the battery 104 by integrating the instantaneous charge energy delivered to the battery 104 from the charging station 124. The computer system 134 and/or its processing circuitry 136 may also be configured to wait for a predetermined amount of time before communicating the first charge request 200T(7) to the charging station 124 after detecting the cells of the battery 104 are at the first predetermined lower voltage in the discharge mode (block 518 in FIG. 5B) to allow the energy stored in the cells of the battery 104 to balance.

The computer system 134 and/or its processing circuitry 136 may request that the charging station 124 to charge the battery 104 initially with a second higher steady state current until its battery 104 until the battery cells of the battery 104 achieve voltage equalization for a full charge. This has the advantage of providing an initial fast charging time, but as the SOC of the battery 104 approaches its maximum SOC, a second lower steady state current can be requested for charging to avoid excess energy resulting in heat generation through losses which can increase battery 104 aging and degrade battery capacity.

In this regard, as shown in FIG. 5B, the computer system 134 and/or its processing circuitry 136 then detects when the overall voltage of the battery 104 is at a second predetermined higher voltage (e.g., 710-720 V) in the charge mode (block 526 in FIG. 5B). This is an indication of overall voltage equalization in the battery 104. In response to detect when the overall voltage of the battery 104 is at a second predetermined higher voltage, the computer system 134 and/or its processing circuitry 136 then communicates a second charge requests 200T(8) to the charging station 124 to request delivering of charge energy to charge the batter 104 at a second lower steady state current (e.g., <5 A) lower than the second higher steady state current for the first charge request 200T(7) (block 528 in FIG. 5B). The computer system 134 and/or its processing circuitry 136 continues to measure the charge energy delivered to the battery 104 (block 524 in FIG. 5B). The computer system 134 and/or its processing circuitry 136 detects when the voltage of the cells of the battery 104 are at the second predetermined higher voltage (e.g., 3.78 V=720 V/190 battery cells) in the charge mode (block 526 in FIG. 5B). This is an indication that all the cells of the battery 104 have been fully charged or are charged to the desired voltage. In response to detecting the voltage of the cells of the battery 104 are at the second predetermined higher voltage in the charge mode, the computer system 134 and/or its processing circuitry 136 disables the discharge/charge mode by communicating a discharge/charge mode request 200T(9) to the charging station 124 to discontinue charging (block 530 in FIG. 5B). The computer system 134 and/or its processing circuitry 136 may be configured to store the non-charge mode in the operational mode indicator 142 in response to receiving the first discharge request 200T(9).

Note that as discussed above, the EV 102 and/or its computer system 134 or its processing circuitry 136, or the on-board battery SOC estimation system 138 can use the measured energy transferred during the discharge and charge cycles with the battery 104 as part of the discharge/charge process 500 in FIGS. 5A and 5B to determine the battery capacity of the battery 104. The measured discharge and charge energy (e.g., stored in the energy measurement indicator 146 in the memory 144) can be displayed to a technician or an operator of the EV 102. The technician or operator of the EV can use the determined battery capacity of the battery 104 of the EV 102 to determine if the battery 104 should be repaired or replaced. Also, the determined battery capacity of the battery 104 can be used by the EV 102 to update the battery SOC estimation system 138 and algorithm so that a more accurate SOC can be determined and/or displayed to the operator of the EV 102. The TOD considerations discussed above with regard to the discharge/charge processes 300, 300(1) in FIGS. 3A and 3B can also be used in the discharge/charge process 500 in FIGS. 5A and 5B.

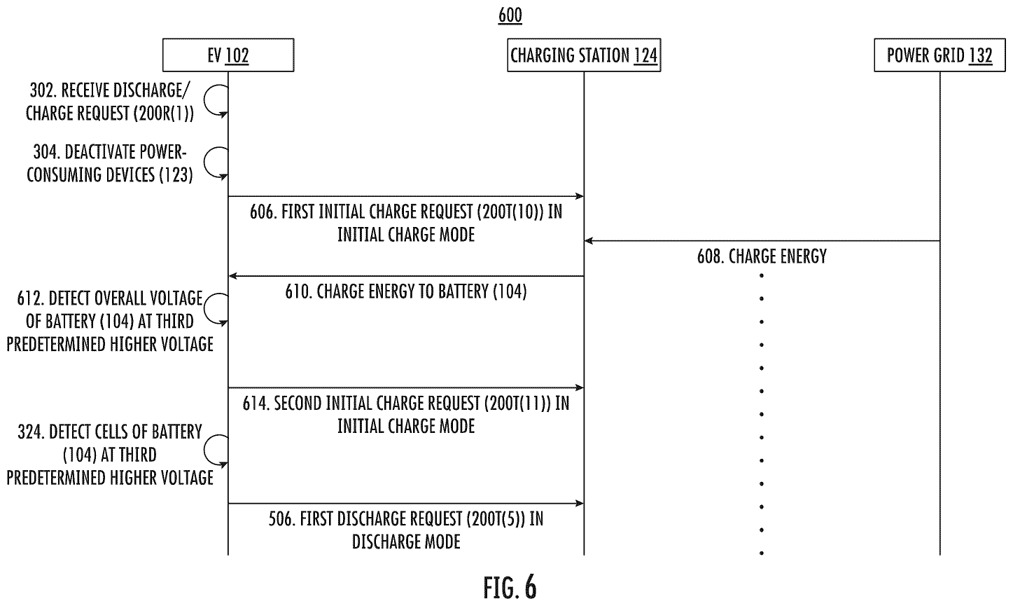

FIG. 6 is an alternative discharge/charge process 600 that includes the computer system 134 and/or its processing circuitry 136 performing an optional initial charge of the battery 104 to then perform the discharge/charge process 500 in FIGS. 5A and 5B. As shown in FIG. 6, the computer system 134 and/or its processing circuitry 136 receives the discharge/charge request 200R(1) for the EV 102 to enter the discharge/charge operational mode while the vehicle charging port 130 of the EV 102 is coupled to the charging station 124 configured to operate in a V2G mode (block 302 in FIG. 6). Then, in response to the request for the EV 102 to enter a discharge/charge operational mode to perform the discharge/charge process 600 in step 302, the computer system 134 and/or its processing circuitry 136 deactivates (e.g., turns off, idles) power-consuming devices 123 in the EV 102 that are not essential to the EV 102 operating in the discharge/charge operational mode (block 304 in FIG. 6). This has been previously described in the discharge/charge processes 300, 300(1) in FIGS. 3A and 3B.

With continuing reference to FIG. 6, instead of communicating the first discharge request 200T(5) to the charging station 124 as discussed in block 506 in the discharge/charge process 500 in FIG. 5A, the computer system 134 and/or its processing circuitry 136 communicates a first initial charge request 200T(10) to the charging station 124 in an initial charge mode (block 606 in FIG. 4). The computer system 134 and/or its processing circuitry 136 may be configured to store the initial charge mode in the operational mode indicator 142 in response to receiving the first initial charge request 200T(10). The first initial charge request 200T(10) can be part of a transmission signal 200T communicated from the EV 102 over the charging cable 126 to the charging station 124 as shown in FIG. 2 as an example. This causes the charging station 124 to transfer energy received from the power grid 132 (block 608 in FIG. 6) to the battery 104 over the charging cable 126 (block 610 in FIG. 6) to initially charge the battery 104. In an example, in the initial charge mode, the EV 102 communicates the first initial charge request 200T(10) to the charging station 124 to instruct the charging station 124 to deliver charge energy to the battery 104 of the EV 102 at a third higher current (e.g. 5 A to 50 A) in the initial charge mode so that charging will occur faster.

In the initial charge mode charge energy is delivered to the battery 104 for charging (block 608 in FIG. 6) from the power grid 132 and through the charging station 124 (block 610 in FIG. 6). The computer system 134 and/or its processing circuitry 136 detects when an overall voltage of the battery 104 reaches a third predetermined higher voltage (e.g., 710-720 V in an 800V charging system) indicating that the battery 104 is almost fully charged (block 612 in FIG. 6). In response to detecting the overall voltage of the battery 104 reaching the third predetermined higher voltage indicating that the battery 104 is almost fully charged (block 612 in FIG. 6), the computer system 134 and/or its processing circuitry 136 communicates a second initial charge request 200T(11) to the charging station 124 to charge the battery 104 at a third lower current (e.g., <5 A) lower than the third higher current in the initial charge mode (block 614 in FIG. 6). This is so that excess heat is not generated from charging the battery 104 leading to losses and battery 104 degradation. The computer system 134 and/or its processing circuitry 136 then detects when the cells of the battery 104 reach the third predetermined higher voltage signifying voltage equalization in the cells of the battery 104 indicating a full charge (block 616 in FIG. 6). In response to detecting when the cells of the battery 104 reach the third predetermined higher voltage (e.g., (e.g., 3.78 V=720 V/190 battery cells) signifying voltage equalization in the cells of the battery 104 indicating a full charge (block 616 in FIG. 6), the computer system 134 and/or its processing circuitry 136 enters into the discharge mode by communicating the first discharge request 200T(5) to the charging station 124 to discharge the battery 104 shown in block 506 in FIG. 6). The computer system 134 and/or its processing circuitry 136 may be configured to store the discharge mode in the operational mode indicator 142 in response to receiving the first discharge request 200T(5). The remainder of this alternative discharge/charge process 600 can be performed starting at block 506 in FIG. 5A and continuing to block 530 in FIG. 5B just as described above.

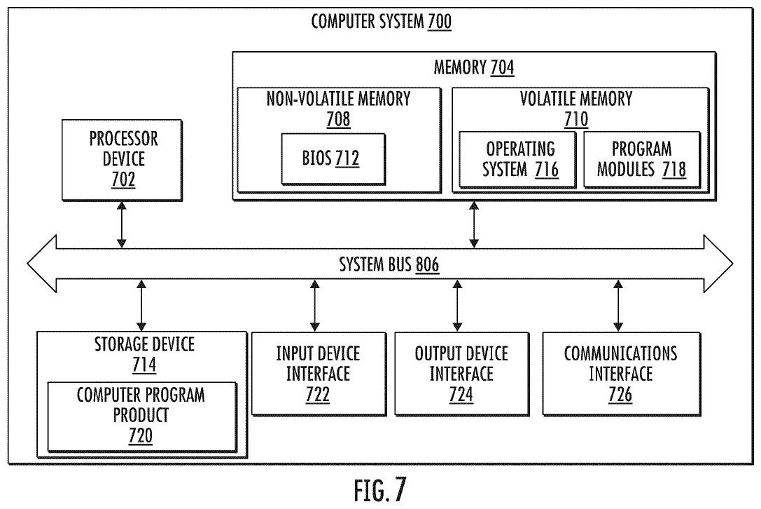

FIG. 7 is a block diagram of a computer system 700 for implementing any examples disclosed herein. For example, the computer system 134, its processing circuitry 136, and the on-board battery SOC estimation system 138, could each be provided by the computer system 700 in FIG. 7. The computer system 700 is adapted to execute instructions from a computer-readable medium to perform these and/or any of the functions or processing described herein. The computer system 700 may be connected (e.g., networked) to other machines in a local area network (LAN), an intranet, an extranet, or the Internet. While only a single device is illustrated, the computer system 700 may include any collection of devices that individually or jointly execute a set (or multiple sets) of instructions to perform any one or more of the methodologies discussed herein. Accordingly, any reference in the disclosure and/or claims to a computer system, computing system, computer device, computing device, control system, control unit, electronic control unit (ECU), processor device, processing circuitry, etc., includes reference to one or more such devices to individually or jointly execute a set (or multiple sets) of instructions to perform any one or more of the methodologies discussed herein. For example, a control system may include a single control unit or a plurality of control units connected or otherwise communicatively coupled to each other, such that any performed function may be distributed between the control units as desired. Further, such devices may communicate with each other or other devices by various system architectures, such as directly or via a Controller Area Network (CAN) bus, etc.

The computer system 700 may comprise at least one computing device or electronic device capable of including firmware, hardware, and/or executing software instructions to implement the functionality described herein. The computer system 700 may include processing circuitry 702 (e.g., a processor including one or more processor devices or control units), a memory 704, and a system bus 706. The processing circuitry 702 could be the processing circuitry 136 in FIG. 2, as an example. The computer system 700 may include at least one computing device having the processing circuitry 702. The system bus 706 provides an interface for system components including, but not limited to, the memory 704 and the processing circuitry 702. The memory 704 could be used to store the measured discharged energy and/or charge energy discharged and/or used to charge the battery 104 of the EV 102. The memory 704 also stores the algorithm used by the on-board battery SOC estimation system 138 to estimate the SOC of the battery 104. The processing circuitry 702 may include any number of hardware components for conducting data or signal processing or for executing computer code stored in the memory 704. The processing circuitry 702 may, for example, include a general-purpose processor, an application specific processor, a Digital Signal Processor (DSP), an Application Specific Integrated Circuit (ASIC), a Field Programmable Gate Array (FPGA), a circuit containing processing components, a group of distributed processing components, a group of distributed computers configured for processing, or other programmable logic device, discrete gate or transistor logic, discrete hardware components, or any combination thereof designed to perform the functions described herein. The processing circuitry 702 may further include computer executable code that controls operation of the programmable device.

The system bus 706 may be any of several types of bus structures that may further interconnect to a memory bus (with or without a memory controller), a peripheral bus, and/or a local bus using any of a variety of bus architectures. The memory 704 may be one or more devices for storing data and/or computer code for completing or facilitating methods described herein. The memory 704 may include database components, object code components, script components, or other types of information structure for supporting the various activities herein. Any distributed or local memory device may be utilized with the systems and methods of this description. The memory 704 may be communicably connected to the processing circuitry 702 (e.g., via a circuit or any other wired, wireless, or network connection) and may include computer code for executing one or more processes described herein. The memory 704 may include non-volatile memory 708 (e.g., read-only memory (ROM), erasable programmable read-only memory (EPROM), electrically erasable programmable read-only memory (EEPROM), etc.), and volatile memory 710 (e.g., random-access memory (RAM)), or any other medium which can be used to carry or store desired program code in the form of machine-executable instructions or data structures and which can be accessed by a computer or other machine with processing circuitry 702. A basic input/output system (BIOS) 712 may be stored in the non-volatile memory 708 and can include the basic routines that help to transfer information between elements within the computer system 700.

The computer system 700 may further include or be coupled to a non-transitory computer-readable storage medium such as a storage device 714, which may comprise, for example, an internal or external hard disk drive (HDD) (e.g., enhanced integrated drive electronics (EIDE) or serial advanced technology attachment (SATA)), HDD (e.g., EIDE or SATA) for storage, flash memory, or the like. The storage device 714 and other drives associated with computer-readable media and computer-usable media may provide non-volatile storage of data, data structures, computer-executable instructions, and the like.

Computer code which is hard or soft coded may be provided in the form of one or more modules. The module(s) can be implemented as software and/or hard-coded in circuitry to implement the functionality described herein in whole or in part. The modules may be stored in the storage device 714 and/or in the volatile memory 710, which may include an operating system 716 and/or one or more program modules 718. All or a portion of the examples disclosed herein may be implemented as a computer program 720 stored on a transitory or non-transitory computer-usable or computer-readable storage medium (e.g., single medium or multiple media), such as the storage device 714, which includes complex programming instructions (e.g., complex computer-readable program code) to cause the processing circuitry 702 to carry out actions described herein. Thus, the computer-readable program code of the computer program 720 can comprise software instructions for implementing the functionality of the examples described herein when executed by the processing circuitry 702. In some examples, the storage device 714 may be a computer program product (e.g., readable storage medium) storing the computer program 720 thereon, where at least a portion of the computer program 720 may be loadable (e.g., into a processor or processing circuitry) for implementing the functionality of the examples described herein when executed by the processing circuitry 702. The processing circuitry 702 may serve as a controller or control system for the computer system 700 that is to implement the functionality described herein.

The computer system 700 may include an input device interface 722 configured to receive input and selections to be communicated to the computer system 700 when executing instructions, such as from a keyboard, mouse, touch-sensitive surface, etc. Such input devices may be connected to the processing circuitry 702 through the input device interface 722 coupled to the system bus 706 but can be connected through other interfaces, such as a parallel port, an Institute of Electrical and Electronic Engineers (IEEE) 1394 serial port, a Universal Serial Bus (USB) port, an IR interface, and the like. The computer system 700 may include an output device interface 724 configured to forward output, such as to a display, a video display unit (e.g., a liquid crystal display (LCD) or a cathode ray tube (CRT)). The computer system 700 may include a communications interface 726 suitable for communicating with a network as appropriate or desired.

The operational actions described in any of the exemplary aspects herein are described to provide examples and discussion. The actions may be performed by hardware components, may be embodied in machine-executable instructions to cause a processor or processing circuitry to perform the actions, or may be performed by a combination of hardware and software. Although a specific order of method actions may be shown or described, the order of the actions may differ. In addition, two or more actions may be performed concurrently or with partial concurrence.

Implementation examples are described in the following numbered clauses:
Example 1: A computer system comprising processing circuitry configured to:
receive a request for a vehicle to enter a discharge/charge operational mode while a vehicle charging port of the vehicle is coupled to an external charging station configured to operate in a vehicle-to-grid (V2G) mode; and
in response to the request for the vehicle to enter the discharge/charge operational mode:
   deactivate power consuming devices in the vehicle not essential to the vehicle operating in the discharge/charge operational mode;
   communicate a discharge request to the external charging station to discharge energy from a battery in the vehicle to a power grid coupled to the external charging station at a first steady state current in a discharge mode;
   measure the discharged energy from the battery in the discharge mode;
   detect the battery at a first predetermined lower voltage in the discharge mode; and
   in response to detecting the battery at the first predetermined lower voltage in the discharge mode:
      communicate a charge request to the external charging station to deliver charge energy to the battery from the power grid at a second steady state current in a charge mode; and
   measure the charge energy delivered to the battery in the charge mode.
Example 2: The computer system of Example 1, wherein the processing circuitry is configured to communicate the discharge request by being configured to:
communicate a first discharge request to the external charging station to discharge energy from the battery in the vehicle to the power grid coupled to the external charging station at a first higher steady state current in the discharge mode;
detect an overall voltage of the battery at the first predetermined lower voltage in the discharge mode; and
in response to detecting the overall voltage of the battery at the first predetermined lower voltage in the discharge mode:
   communicate a second discharge request to the external charging station to discharge energy from the battery in the vehicle to the power grid at a first lower steady state current lower than the first higher steady state current in the discharge mode;
   detect a voltage of cells of the battery at the first predetermined lower voltage in the discharge mode; and
   in response to detecting the voltage of the cells of the battery at the first predetermined lower voltage in the discharge mode:
      communicate the charge request to the external charging station to deliver the charge energy to the battery from the power grid at the second steady state current in the charge mode; and
   measure the charge energy delivered to the battery in the charge mode.
Example 3: The computer system of Example 2, wherein:
the first predetermined lower voltage is approximately 610-620 Volts (V);
the first lower steady state current is less than 5 Amps (A); and
the first higher steady state current is between 5 A and 50 A.
Example 4: The computer system of Example 1, wherein the processing circuitry is further configured to, in response to detecting the battery at the first predetermined lower voltage in the discharge mode, wait for a predetermined amount of time before communicating the charge request to the external charging station.
Example 5: The computer system of any of Examples 1-4, wherein the processing circuitry is configured to:
detect when the battery is at a second predetermined higher voltage in the charge mode; and
in response to detecting the battery is at the second predetermined higher voltage in the charge mode:
   disable the discharge/charge operational mode.
Example 6: The computer system of Example 5, wherein the processing circuitry is configured to communicate the charge request by being configured to:
communicate a first charge request to the external charging station to deliver the charge energy to the battery from the power grid at a second higher steady state current in the charge mode;
detect an overall voltage of the battery at the second predetermined higher voltage in the charge mode; and
in response to detecting the overall voltage of the battery at the second predetermined higher voltage in the charge mode:
   communicate a second charge request to the external charging station to deliver the charge energy to the battery from the power grid at a second lower steady state current lower than the second higher steady state current in the charge mode;
   detect a voltage of cells of the battery at the second predetermined higher voltage in the charge mode; and
   in response to detecting the voltage of the cells of the battery at the second predetermined higher voltage in the charge mode:
   disable the discharge/charge operational mode.
Example 7: The computer system of Example 6, wherein:
the second predetermined higher voltage is approximately 710-720 Volts (V);
the second lower steady state current lower is less than 5 Amps (A); and
the second higher steady state current lower is greater than 5 A.
Example 8: The computer system of Example 2, wherein the processing circuitry is configured to communicate the charge request by being configured to:
communicate a first charge request to the external charging station to deliver the charge energy to the battery from the power grid at a second higher steady state current in the discharge mode;
detect an overall voltage of the battery at a second predetermined higher voltage in the charge mode; and
in response to detecting the overall voltage of the battery at the second predetermined higher voltage in the charge mode:
   communicate a second charge request to the external charging station to deliver the charge energy to the battery from the power grid at a second lower steady state current lower than the second higher steady state current in the charge mode;
   detect a voltage of the cells of the battery at the second predetermined higher voltage in the charge mode; and
   in response to detecting the voltage of the cells of the battery at the second predetermined higher voltage in the charge mode:
      disable the discharge/charge operational mode.
Example 9: The computer system of any of Examples 5-7, wherein the processing circuitry is further configured to, in response to the request for the vehicle to enter the discharge/charge operational mode, prior to communicating the discharge request:
communicate an initial charge request to the external charging station to deliver initial charge energy to the battery from the power grid at a third current in an initial charge mode; and
detect when the battery is at a third predetermined higher voltage in the initial charge mode; and
in response to detecting the battery is at the third predetermined higher voltage in the initial charge mode:
   communicate the discharge request to the external charging station.
Example 10: The computer system of Example 9, wherein the processing circuitry is configured to communicate the initial charge request by being configured to:
communicate a first initial charge request to the external charging station to deliver the charge energy to the battery from the power grid at a third higher current in the initial charge mode;
detect an overall voltage of the battery at the third predetermined higher voltage in the initial charge mode; and
in response to detecting the overall voltage of the battery at the third predetermined higher voltage in the initial charge mode:
   communicate a second initial charge request to the external charging station to deliver the charge energy to the battery from the power grid at a third lower current lower than the third higher current in the initial charge mode;
   detect a voltage of cells of the battery at the third predetermined higher voltage in the initial charge mode; and
   in response to detecting the voltage of the cells of the battery at the third predetermined higher voltage in the initial charge mode:
      communicate the discharge request to the external charging station.
Example 11: The computer system of Example 10, wherein:
the third predetermined higher voltage is approximately 710-720 Volts (V);
the third lower current is less than 5 Amps (A); and
the third higher current is between 5 A and 50A.
Example 12: The computer system of any of Examples 1-11, wherein the processing circuitry is further configured to:
store the measured discharged energy discharged from the battery in the discharge mode; and
store the measured charge energy delivered to the battery in the charge mode.
Example 13: The computer system of Example 12, wherein the processing circuitry is further configured to calibrate battery state-of-charge (SOC) estimation system based on at least one of the measured discharged energy discharged from the battery in the discharge mode, and the measured charge energy delivered to the battery in the charge mode.
Example 14: The computer system of any of Examples 1-13, wherein the processing circuitry is further configured to schedule the discharge/charge operational mode based on a time-of-day (TOD) schedule.
Example 15: The computer system of any of Examples 1-13, wherein the processing circuitry is further configured to:
communicate the discharge request at a first scheduled time based on a higher cost energy rate of a time-of-day (TOD) schedule; and
communicate the charge request at a second scheduled time based on a lower cost energy rate of a TOD schedule, wherein the lower cost energy rate is lower than the higher cost energy rate.
Example 16: The computer system of any of Examples 1-13, wherein the processing circuitry is further configured to:
communicate the discharge request at a first scheduled time based on a higher energy demand of a time-of-day (TOD) schedule; and
communicate the charge request at a second scheduled time based on a lower energy demand of a TOD schedule, wherein the lower energy demand is lower than the higher energy demand.
Example 17: A vehicle comprising the computer system of any of Examples 1-16.
Example 18: A computer-implemented method, comprising:
receiving, by processing circuitry of a computer system, a request for a vehicle to enter a discharge/charge operational mode while a vehicle charging port of the vehicle is coupled to an external charging station configured to operate in a vehicle-to-grid (V2G) mode; and
in response to the request for the vehicle to enter the discharge/charge operational mode:
   deactivating, by the processing circuitry of the computer system, power consuming devices in the vehicle not essential to the vehicle operating in the discharge/charge operational mode;
   communicating, by the processing circuitry of the computer system, a discharge request to the external charging station to discharge energy from a battery in the vehicle to a power grid coupled to the external charging station at a first steady state current in a discharge mode;
   measuring, by the processing circuitry of the computer system, the discharged energy from the battery in the discharge mode;
   detecting, by the processing circuitry of the computer system, the battery at a first predetermined lower voltage in the discharge mode; and
   in response to detecting the battery at the first predetermined lower voltage in the discharge mode:
      communicating, by the processing circuitry of the computer system, a charge request to the external charging station to deliver charge energy to the battery from the power grid at a second steady state current in a charge mode; and
      measuring, by the processing circuitry of the computer system, the charge energy delivered to the battery in the charge mode.
Example 19: A computer program product comprising program code for performing, when executed by processing circuitry, the method of Example 18.
Example 20: A non-transitory computer-readable storage medium comprising instructions, which when executed by processing circuitry, cause the processing circuitry to perform the method of Example 18.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. As used herein, the term “and/or” includes any and all combinations of one or more of the associated listed items. It will be further understood that the terms “comprises,” “comprising,” “includes,” and/or “including” when used herein specify the presence of stated features, integers, actions, steps, operations, elements, and/or components, but do not preclude the presence or addition of one or more other features, integers, actions, steps, operations, elements, components, and/or groups thereof.

It will be understood that, although the terms first, second, etc., may be used herein to describe various elements, these elements should not be limited by these terms. These terms are only used to distinguish one element from another. For example, a first element could be termed a second element, and, similarly, a second element could be termed a first element without departing from the scope of the present disclosure.

Relative terms such as “below” or “above” or “upper” or “lower” or “horizontal” or “vertical” may be used herein to describe a relationship of one element to another element as illustrated in the Figures. It will be understood that these terms and those discussed above are intended to encompass different orientations of the device in addition to the orientation depicted in the Figures. It will be understood that when an element is referred to as being “connected” or “coupled” to another element, it can be directly connected or coupled to the other element, or intervening elements may be present. In contrast, when an element is referred to as being “directly connected” or “directly coupled” to another element, there are no intervening elements present.

Unless otherwise defined, all terms (including technical and scientific terms) used herein have the same meaning as commonly understood by one of ordinary skill in the art to which this disclosure belongs. It will be further understood that terms used herein should be interpreted as having a meaning consistent with their meaning in the context of this specification and the relevant art and will not be interpreted in an idealized or overly formal sense unless expressly so defined herein.

It is to be understood that the present disclosure is not limited to the aspects described above and illustrated in the drawings; rather, the skilled person will recognize that many changes and modifications may be made within the scope of the present disclosure and appended claims. In the drawings and specification, there have been disclosed aspects for purposes of illustration only and not for purposes of limitation, the scope of the disclosure being set forth in the following claims.

What is claimed is:

1. A computer system comprising processing circuitry configured to:
receive a request for a vehicle to enter a discharge/charge operational mode while a vehicle charging port of the vehicle is coupled to an external charging station configured to operate in a vehicle-to-grid (V2G) mode; and
in response to the request for the vehicle to enter the discharge/charge operational mode:
deactivate power consuming devices in the vehicle not essential to the vehicle operating in the discharge/charge operational mode;
communicate a first discharge request to the external charging station to discharge energy from a battery in the vehicle to a power grid coupled to the external charging station at a first higher steady state current in a discharge mode;
detect an overall voltage of the battery at the first predetermined lower voltage in the discharge mode; and
in response to detecting the overall voltage of the battery at the first predetermined lower voltage in the discharge mode: communicate a second discharge request to the external charging station to discharge energy from the battery in the vehicle to the power grid at a first lower steady state current lower than the first higher steady state current in the discharge mode;
detect a voltage of cells of the battery at the first predetermined lower voltage in the discharge mode; and
in response to detecting the voltage of the cells of the battery at the first predetermined lower voltage in the discharge mode:
communicate the charge request to the external charging station to deliver the charge energy to the battery from the power grid at the second steady state current in the charge mode; and
measure the discharged energy from the battery in the discharge mode;
detect the battery at a first predetermined lower voltage in the discharge mode; and
in response to detecting the battery at the first predetermined lower voltage in the discharge mode:
communicate a charge request to the external charging station to deliver charge energy to the battery from the power grid at a second steady state current in a charge mode; and
measure the charge energy delivered to the battery in the charge mode;
detect when the battery is at a second predetermined higher voltage in the charge mode; and
in response to detecting the battery is at the second predetermined higher voltage in the charge mode:
disable the discharge/charge operational mode.

2. The computer system of claim 1, wherein:
the first predetermined lower voltage is approximately 610-620 Volts (V);
the first lower steady state current is less than 5 Amps (A); and
the first higher steady state current is between 5 A and 50 A.

3. The computer system of claim 1, wherein the processing circuitry is further configured to, in response to detecting the battery at the first predetermined lower voltage in the discharge mode, wait for a predetermined amount of time before communicating the charge request to the external charging station.

4. The computer system of claim 1, wherein the processing circuitry is configured to:
detect when the battery is at a second predetermined higher voltage in the charge mode; and
in response to detecting the battery is at the second predetermined higher voltage in the charge mode:
disable the discharge/charge operational mode.

5. The computer system of claim 4, wherein the processing circuitry is configured to communicate the charge request by being configured to:
communicate a first charge request to the external charging station to deliver the charge energy to the battery from the power grid at a second higher steady state current in the charge mode;
detect an overall voltage of the battery at the second predetermined higher voltage in the charge mode; and
in response to detecting the overall voltage of the battery at the second predetermined higher voltage in the charge mode:
communicate a second charge request to the external charging station to deliver the charge energy to the battery from the power grid at a second lower steady state current lower than the second higher steady state current in the charge mode;
detect a voltage of cells of the battery at the second predetermined higher voltage in the charge mode; and
in response to detecting the voltage of the cells of the battery at the second predetermined higher voltage in the charge mode:
disable the discharge/charge operational mode.

6. The computer system of claim 5, wherein:
the second predetermined higher voltage is approximately 710-720 Volts (V);
the second lower steady state current lower is less than 5 Amps (A); and
the second higher steady state current lower is greater than 5 A.

7. The computer system of claim 1, wherein the processing circuitry is configured to communicate the charge request by being configured to:
communicate a first charge request to the external charging station to deliver the charge energy to the battery from the power grid at a second higher steady state current in the discharge mode;
detect an overall voltage of the battery at a second predetermined higher voltage in the charge mode; and
in response to detecting the overall voltage of the battery at the second predetermined higher voltage in the charge mode:
communicate a second charge request to the external charging station to deliver the charge energy to the battery from the power grid at a second lower steady state current lower than the second higher steady state current in the charge mode;
detect a voltage of the cells of the battery at the second predetermined higher voltage in the charge mode; and
in response to detecting the voltage of the cells of the battery at the second predetermined higher voltage in the charge mode:
disable the discharge/charge operational mode.

8. The computer system of claim 4, wherein the processing circuitry is further configured to, in response to the request for the vehicle to enter the discharge/charge operational mode, prior to communicating the discharge request:
communicate an initial charge request to the external charging station to deliver initial charge energy to the battery from the power grid at a third current in an initial charge mode; and
detect when the battery is at a third predetermined higher voltage in the initial charge mode; and
in response to detecting the battery is at the third predetermined higher voltage in the initial charge mode:
communicate the discharge request to the external charging station.

9. The computer system of claim 8, wherein the processing circuitry is configured to communicate the initial charge request by being configured to:
communicate a first initial charge request to the external charging station to deliver the charge energy to the battery from the power grid at a third higher current in the initial charge mode;
detect an overall voltage of the battery at the third predetermined higher voltage in the initial charge mode; and
in response to detecting the overall voltage of the battery at the third predetermined higher voltage in the initial charge mode:
communicate a second initial charge request to the external charging station to deliver the charge energy to the battery from the power grid at a third lower current lower than the third higher current in the initial charge mode;
detect a voltage of cells of the battery at the third predetermined higher voltage in the initial charge mode; and
in response to detecting the voltage of the cells of the battery at the third predetermined higher voltage in the initial charge mode:
communicate the discharge request to the external charging station.

10. The computer system of claim 9, wherein:
the third predetermined higher voltage is approximately 710-720 Volts (V);
the third lower current is less than 5 Amps (A); and
the third higher current is between 5 A and 50A.

11. The computer system of claim 1, wherein the processing circuitry is further configured to:
store the measured discharged energy discharged from the battery in the discharge mode; and
store the measured charge energy delivered to the battery in the charge mode.

12. The computer system of claim 11, wherein the processing circuitry is further configured to calibrate battery state-of-charge (SOC) estimation system based on at least one of the measured discharged energy discharged from the battery in the discharge mode, and the measured charge energy delivered to the battery in the charge mode.

13. The computer system of claim 1, wherein the processing circuitry is further configured to schedule the discharge/charge operational mode based on a time-of-day (TOD) schedule.

14. The computer system of claim 1, wherein the processing circuitry is further configured to:
communicate the discharge request at a first scheduled time based on a higher cost energy rate of a time-of-day (TOD) schedule; and
communicate the charge request at a second scheduled time based on a lower cost energy rate of a TOD schedule, wherein the lower cost energy rate is lower than the higher cost energy rate.

15. The computer system of claim 1, wherein the processing circuitry is further configured to:
communicate the discharge request at a first scheduled time based on a higher energy demand of a time-of-day (TOD) schedule; and
communicate the charge request at a second scheduled time based on a lower energy demand of a TOD schedule, wherein the lower energy demand is lower than the higher energy demand.

16. A vehicle comprising the computer system of claim 1.

17. A computer-implemented method, comprising:
receiving, by processing circuitry of a computer system, a request for a vehicle to enter a discharge/charge operational mode while a vehicle charging port of the vehicle is coupled to an external charging station configured to operate in a vehicle-to-grid (V2G) mode; and
in response to the request for the vehicle to enter the discharge/charge operational mode:
deactivating, by the processing circuitry of the computer system, power consuming devices in the vehicle not essential to the vehicle operating in the discharge/charge operational mode;
communicating, by the processing circuitry of the computer system, a first discharge request to the external charging station to discharge energy from a battery in the vehicle to a power grid coupled to the external charging station at a first higher steady state current in a discharge mode;
detecting an overall voltage of the battery at the first predetermined lower voltage in the discharge mode; and
in response to detecting the overall voltage of the battery at the first predetermined lower voltage in the discharge mode:
communicating a second discharge request to the external charging station to discharge energy from the battery in the vehicle to the power grid at a first lower steady state current lower than the first higher steady state current in the discharge mode;
detecting a voltage of cells of the battery at the first predetermined lower voltage in the discharge mode; and
in response to detecting the voltage of the cells of the battery at the first predetermined lower voltage in the discharge mode:
communicating the charge request to the external charging station to deliver the charge energy to the battery from the power grid at the second steady state current in the charge mode; and measuring, by the processing circuitry of the computer system, the discharged energy from the battery in the discharge mode;
detecting, by the processing circuitry of the computer system, the battery at a first predetermined lower voltage in the discharge mode; and
in response to detecting the battery at the first predetermined lower voltage in the discharge mode:
communicating, by the processing circuitry of the computer system, a charge request to the external charging station to deliver charge energy to the battery from the power grid at a second steady state current in a charge mode;
measuring, by the processing circuitry of the computer system, the charge energy delivered to the battery in the charge mode;
detecting when the battery is at a second predetermined higher voltage in the charge mode; and
in response to detecting the battery is at the second predetermined higher voltage in the charge mode:
disabling the discharge/charge operational mode.

18. A computer program product comprising program code for performing, when executed by processing circuitry, the method of claim 17.

19. A non-transitory computer-readable storage medium comprising instructions, which when executed by processing circuitry, cause the processing circuitry to perform the method of claim 17.
